(19) United States
(12) Patent Application Publication
(10) Pub. No.: US 2007/0076494 A1
(43) Pub. Date: Apr. 5, 2007

(54) SEMICONDUCTOR INTEGRATED CIRCUIT DEVICE

(76) Inventors: Ken Takeuchi, Yokohama-shi (JP); Tomoharu Tanaka, Yokohama-shi (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 11/533,061

(22) Filed: Sep. 19, 2006

(30) Foreign Application Priority Data
Sep. 30, 2005 (JP) 2005-288566

(51) Int. Cl. G11C 29/00

(52) U.S. Cl. 365/200

(57) ABSTRACT

A semiconductor integrated circuit device includes a memory cell section containing memory cells, bit lines connected to one end of the memory cell section, and a data circuit connected to the bit lines to temporarily store one of write data and read data with respect to the memory cell. Each of the bit lines includes N sub-bit lines and (N-1) transfer gate portions. Each of the transfer gate portions includes a selection transistor.

### CROSS-REFERENCE TO RELATED APPLICATIONS

This application is based upon and claims the benefit of priority from prior Japanese Patent Application No. 2005-288566, filed Sep. 30, 2005, the entire contents of which are incorporated herein by reference.

### BACKGROUND OF THE INVENTION

1. Field of the Invention

This invention relates to a semiconductor integrated circuit device and more particularly to a semiconductor integrated circuit device having an electrically rewritable nonvolatile semiconductor memory device.

2. Description of the Related Art

Recently, in an electrically rewritable nonvolatile semiconductor memory device, for example, in a NAND flash memory, the memory capacity is rapidly increased on a large scale to lower the unit price of each bit, for example. As the memory capacity is further increased, the number of memory cells connected to a bit line becomes larger. This means that the bit line capacity is increased. Further, an increase in the memory capacity causes the integrated circuit to be further miniaturized. As miniaturization proceeds, the distance between the bit lines is reduced. As a result, the capacitance between the bit lines tends to increase.

If a current flowing in the memory cell which is subjected to a read operation is given as Icell and the bit line capacitance is given as CBL, then the read time TR can be expressed by the following equation.
TR=CBL/Icell+α

As can be understood from the above equation, the read time TR becomes longer if the bit line capacitance CBL is increased. In this case, α indicates time associated with the read operation, for example, time required for precharging the bit line and time required for sensing potential of the bit line.

Further, since the verify read time during the write operation or erase operation becomes long if the read time TR becomes long, the write time and erase time become long.

Reference Document: U.S. Pat. No. 6,643,188

### BRIEF SUMMARY OF THE INVENTION

According to one aspect of this invention, a semiconductor integrated circuit device comprises a memory cell section containing memory cells, bit lines connected to one end of the memory cell section, and a data circuit connected to the bit lines to temporarily store one of write data and read data with respect to the memory cell, wherein each of the bit lines includes N sub-bit lines and (N-1) transfer gate portions and each of the transfer gate portions includes a selection transistor.

According to another aspect of this invention, a semiconductor integrated circuit device comprises a memory cell section containing NAND memory cells each having a plurality of nonvolatile semiconductor memory cells and a selection transistor serially connected, bit lines connected to one end of the memory cell section, and a data circuit connected to the bit lines to temporarily store one of write data and read data with respect to the NAND memory cell, wherein each of the bit lines includes N sub-bit lines and (N-1) transfer gate portions and each of the transfer gate portions includes at least one selection transistor.

### BRIEF DESCRIPTION OF THE SEVERAL VIEWS OF THE DRAWING

FIG. 1 is a block diagram showing one example of a semiconductor integrated circuit device according to a first embodiment of this invention;

FIG. 2 is a diagram showing one example of a memory cell array shown in FIG. 1;

FIG. 3 is a cross-sectional view showing one example of the structure in the column direction of the memory cell array shown in FIG. 1;

FIG. 4 is a cross-sectional view showing one example of the structure in the row direction of the memory cell array shown in FIG. 1;

FIG. 5 is a cross-sectional view showing one example of the structure in the row direction of the memory cell array shown in FIG. 1;

FIG. 6 is a block diagram showing one example of a column control circuit shown in FIG. 1;

FIG. 7 is a diagram showing the relation between multi-level data and the threshold voltage of the memory cell;

FIG. 8 is a diagram showing a typical write method and threshold voltage control operation;

FIG. 9 is a diagram showing a write method and threshold voltage control operation of the semiconductor integrated circuit device according to the first embodiment;

FIG. 10 is a diagram showing a write method of upper page data and a threshold voltage control operation of the semiconductor integrated circuit device according to the first embodiment;

FIG. 11 is an operation waveform diagram showing waveforms at the write time of lower page data of the semiconductor integrated circuit device according to the first embodiment;

FIG. 12 is a flow chart showing a write algorithm of lower page data of the semiconductor integrated circuit device according to the first embodiment;

FIG. 13 is a flow chart showing a write algorithm of upper page data of the semiconductor integrated circuit device according to the first embodiment;

FIGS. 14A to 14C are views and diagram showing situations caused by miniaturization of the processing dimensions;

FIG. 15 is a diagram showing an order of write operations in the blocks;

FIG. 16 is a diagram showing a read algorithm of lower page data of the semiconductor integrated circuit device according to the first embodiment;

FIG. 17 is a diagram showing a read algorithm of upper page data of the semiconductor integrated circuit device according to the first embodiment;

FIG. 18A is an operation waveform diagram showing a write step example 1;

FIG. 18B is an operation waveform diagram showing a write step example 2;

FIG. 19 is an operation waveform diagram showing a modification of the write verify operation;

FIG. 20 is a plan view showing one example of the semiconductor integrated circuit device according to the first embodiment of this invention;

FIG. 21 is a circuit diagram showing one example of the equivalent circuit of a memory cell array shown in FIG. 20;

FIG. 22 is a circuit diagram showing a first example of a transfer gate;

FIG. 23 is a circuit diagram showing a second example of the transfer gate;

FIG. 24 is a circuit diagram showing a third example of the transfer gate;

FIG. 25 is a circuit diagram showing a fourth example of the transfer gate;

FIG. 26 is a plan view showing one example of a semiconductor integrated circuit device according to a second embodiment of this invention; and

FIG. 27 is a plan view showing one example of a semiconductor integrated circuit device according to a third embodiment of this invention.

### DETAILED DESCRIPTION OF THE INVENTION

Embodiments of this invention will now be described with reference to the accompanying drawings. In this explanation, common reference symbols are assigned to common portions throughout the drawings.

### First Embodiment

In a semiconductor integrated circuit device according to a first embodiment of this invention, basically, the read, write and erase operation speeds are enhanced by apparently reducing the bit line capacitance CBL.

For this purpose, in the first embodiment, a bit line is formed to include N sub-bit lines and (N-1) transfer gate portions.

When a memory cell connected to a sub-bit line which is located in the farthest position from a data circuit is accessed, all of the (N-1) transfer gate portions are made conductive. In this case, the bit line capacitance CBL corresponds to the N sub-bit lines.

When a memory cell connected to a sub-bit line which is located in the next-farthest position from the data circuit is accessed, one of the transfer gate portions which is located in the farthest position from the data circuit is cut off. As a result, the bit line capacitance CBL corresponds to the (N-1) sub-bit lines. Thus, the bit line capacitance CBL is apparently reduced.

When three or more sub-bit lines are provided, the bit line capacitance CBL can be apparently sequentially reduced by controlling the transfer gate portions as described above.

Thus, in the first embodiment, the read, write and erase operation speeds can be enhanced since the bit line capacitance CBL can be apparently reduced.

There will now be described the first embodiment of this invention with reference to the accompanying drawings.

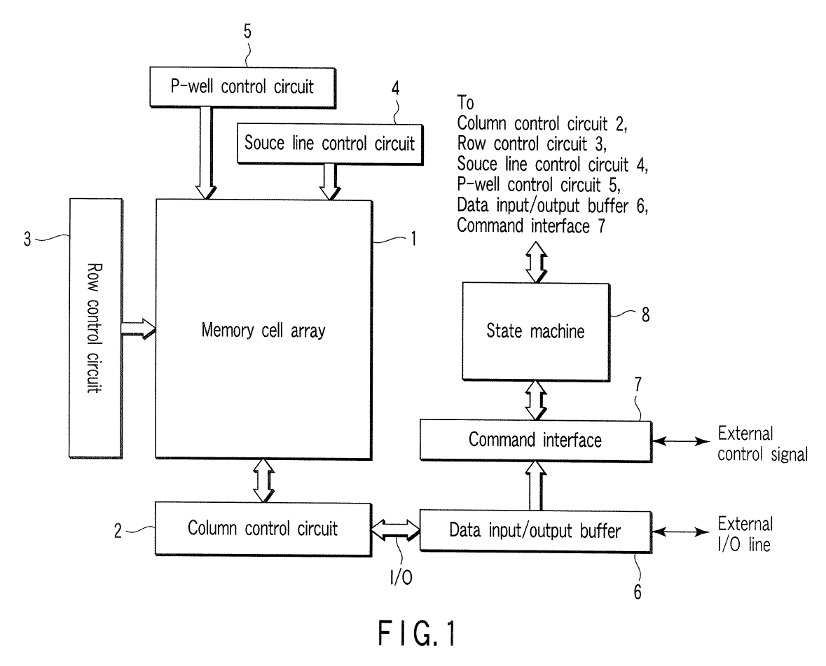

FIG. 1 is a block diagram showing one example of a semiconductor integrated circuit device according to the first embodiment of this invention. As one example of the semiconductor integrated circuit device, the first embodiment shows a NAND flash memory, but this invention can be applied to a memory other than a NAND flash memory.

In a memory cell array 1, nonvolatile semiconductor memory cells are arranged in a matrix form. One example of the nonvolatile semiconductor memory cell is a flash memory cell.

A column control circuit 2 controls the bit lines of the memory cell array 1 and performs the operations of erasing data of the memory cell, writing data into the memory cell and reading data from the memory cell. The column control circuit 2 is arranged adjacent to the memory cell array 1.

A row control circuit 3 selects one of the word lines of the memory cell array 1 and applies a voltage necessary for erasing, writing or reading.

A source line control circuit (C-source control circuit) 4 controls the source lines of the memory cell array 1.

A P-type cell well control circuit (C-p-well control circuit) 5 controls the potential of a P-type well in which the memory cell array 1 is formed.

A data input/output buffer 6 is electrically connected to the column control circuit 2 via an I/O line and electrically connected to an external host (not shown) via an external I/O line. For example, in the data input/output buffer 6, an input/output buffer circuit is arranged. The data input/output buffer 6 receives write data, outputs read data and receives address data and command data. The data input/output buffer 6 supplies received write data to the column control circuit 2 via the I/O line and receives data read from the column control circuit 2 via the I/O line. Further, it supplies externally input address data to the column control circuit 2 and row control circuit 3 via a state machine 8 so as to select the address of the memory cell array 1. Also, it supplies command data from the external host to a command interface 7.

The command interface 7 receives a control signal from the external host via an external control signal line and determines whether data input to the data input/output buffer 6 is write data, command data or address data. Then, it transfers the data as reception command data to the state machine 8 if the data is command data.

The state machine 8 manages the whole portion of the flash memory. It receives command data from the external host and performs the read, write, erase and input/output management processes.

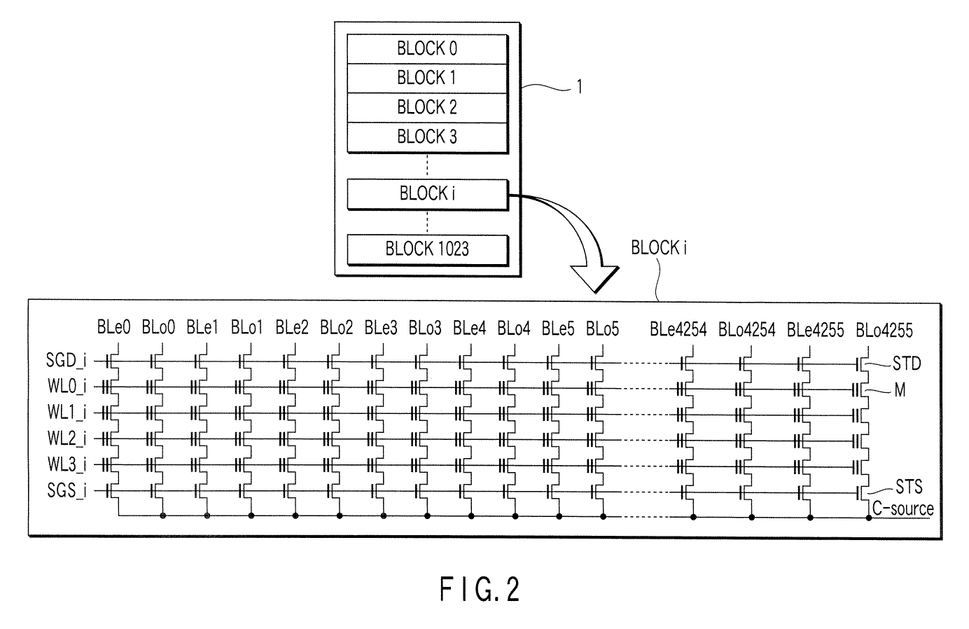

FIG. 2 is a diagram showing one example of the memory cell array 1 shown in FIG. 1.

The memory cell array 1 is divided into a plurality of blocks, for example, 1024 blocks BLOCK0 to BLOCK1023. For example, the block is a minimum unit for erase. Each block BLOCK1 includes a plurality of NAND memory units, for example, 8512 NAND memory units. In this example, each NAND memory unit includes two selection transistors STD, STS and a plurality of memory cells M (in this example, four memory cells M) serially connected between the above two transistors. One end of the NAND memory unit is connected to a corresponding one of the bit lines BL via the selection transistor STD whose gate is connected to a selection gate line SGD and the other end thereof is connected to a common C-source line via the selection transistor STS whose gate is connected to a selection gate line SGS. The gate of each memory cell M is connected to a corresponding one of the word lines WL. The data write and read operations for even-numbered bit lines BLe and odd-numbered bit lines BLo counted from “0” are independently performed. The data write or read operations are simultaneously performed for, for example, 4256 memory cells connected to the bit lines BLe among the 8512 memory cells connected to one word line WL. One-bit data is stored in each memory cell M and data items of 4256 memory cells are collected together to configure a unit which is one page. For example, the page is a minimum unit read. When 2-bit data is stored in each memory cell M, the 4256 memory cells store data of two pages. Likewise, the 4256 memory cells connected to the bit lines BLo configure different two pages and the data write or read operations are simultaneously performed for the memory cells of each page.

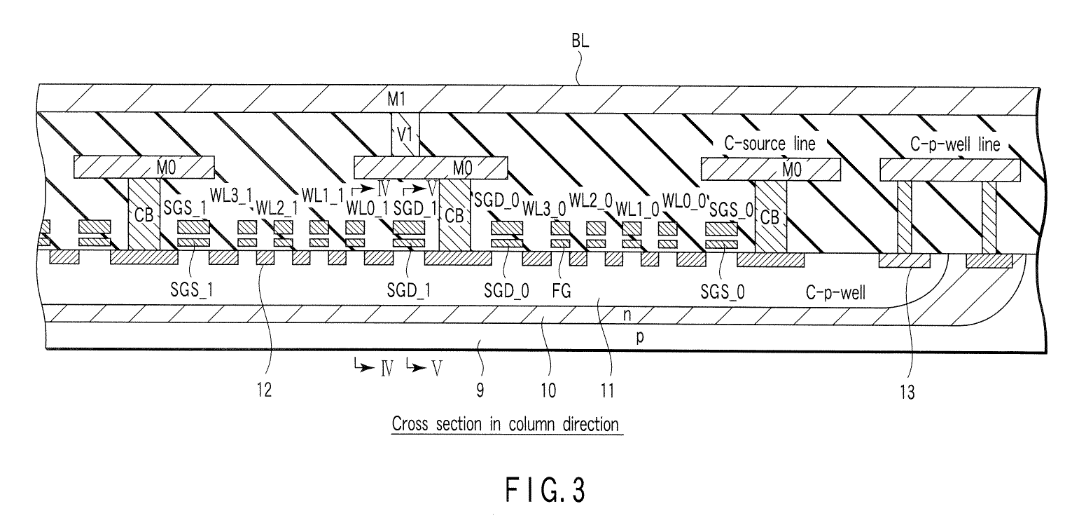

FIG. 3 is a cross-sectional view showing one example of the structure in the column direction of the memory cell array 1 shown in FIG. 1.

An n-type cell well 10 is formed in a p-type semiconductor substrate 9. A p-type cell well 11 is formed in the n-type cell well 10. The memory cell M includes n-type diffusion layers 12 acting as source/drain regions, a floating gate FG, and a control gate acting as the word line WL. The selection gate S (SGS, SGD) includes n-type diffusion layers 12 acting as source/drain regions and a double-structured gate acting as the selection gate SG. The word line WL and selection gate line SG are connected to the row control circuit 3 and controlled by the row control circuit 3.

One end of the NAND memory cell unit is connected to a first metal interconnection layer M0 via a first contact CB and connected to a second metal interconnection layer M1 functioning as the bit line BL via a second contact V1. The bit line BL is connected to the column control circuit 2. The other end of the NAND memory unit is connected to the first metal interconnection layer M0 functioning as the common source line C-source via the first contact hole CB. The common source line C-source is connected to the source line control circuit 4.

The n-type cell well 10 and p-type cell well 11 are set at the same potential and connected to the P well control circuit 5 via the well line C-p-well.

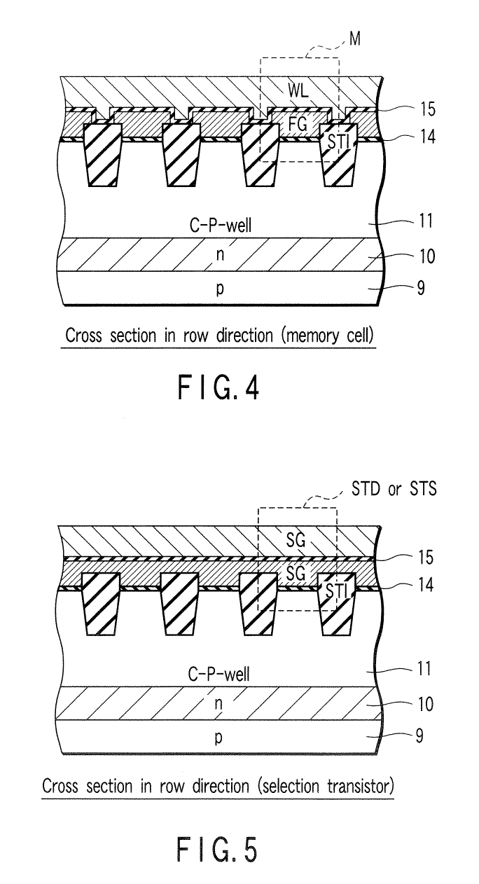

FIGS. 4 and 5 are cross-sectional views showing one example of the structure in the row direction of the memory cell array 1 shown in FIG. 1.

As shown in FIG. 4, the memory cells M are isolated by use of element isolation regions STI. The floating gate FG is stacked on a channel region with a tunnel oxide film 14 disposed therebetween. The word line WL is stacked on the floating gate FG with an onO film 15 disposed therebetween.

As shown in FIG. 5, the selection gate line SG has a double structure. Although not shown in the drawing, the upper and lower selection gate lines SG are connected to one end of the memory cell array 1 or to the bit lines for every preset number.

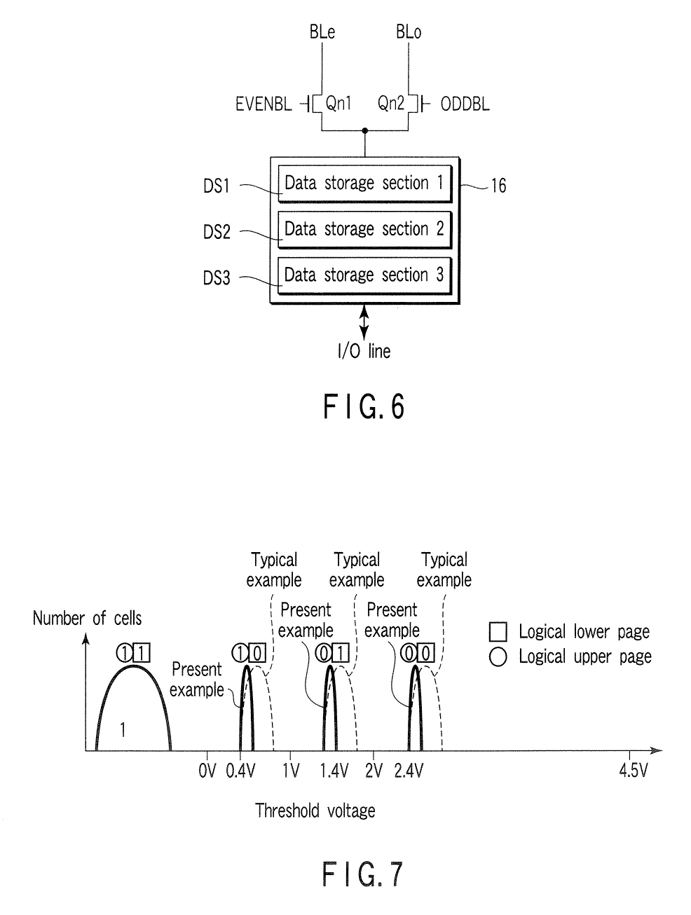

FIG. 6 is a block diagram showing one example of the column control circuit 2 shown in FIG. 1.

Each data storage circuit 16 is provided for every two bit lines (for example, BLe5 and BLo5) of the even-numbered bit line BLe and odd-numbered bit line BLo having the same column number. One of the bit lines BLe and BLo is selected and connected to the data storage circuit 16. Then, the potential of the bit line BLe or BLo is controlled for data write or readout. When a signal EVENBL is made high (“H” level) and a signal ODDBL is made low (“L” level), the bit line BLe is selected. The bit line BLe is connected to the data storage circuit 16 via an n-channel MOS transistor Qn1. On the other hand, when the signal EVENBL is made low and the signal ODDBL is made high, the bit line BLo is selected. The bit line BLo is connected to the data storage circuit 16 via an n-channel MOS transistor Qn2. The signal EVENBL is common for all of the even-numbered bit lines BLe. Likewise, the signal ODDBL is common for all of the odd-numbered bit lines BLo. The non-selected bit lines are controlled by a circuit (not shown).

The data storage circuit 16 includes three binary data storage sections DS1, DS2, DS3. The data storage section DS1 is connected to the data input/output buffer 6 via the data input/output line (I/O line) and stores externally write data input or read data to be externally output. The data storage section DS2 stores a detection result at the time of recognition (write verify) of the threshold voltage of the memory cell M after writing. The data storage section DS3 temporarily stores data of the memory cell M at the write time and read time.

FIG. 7 is a diagram showing the relation between multi-level data of a multi-level flash memory and the threshold voltage of the memory cell M.

In this example, 2-bit data is stored in one memory cell M. As the 2-bit data, “11”, “10”, “00”, “01” are used. The two bits belong to different row addresses (different pages).

After erasing, data of the memory cell M is set to “11”. If lower page data with respect to the memory cell M is “0”, the state is changed from “11” to “10” by writing. When “1” data is written, the state “11” is kept unchanged.

Next, upper page data is written. If data is “1”, the state of “11” or “10” is maintained. If data is “0”, the state of “11” is changed to “01” and the state “10” is changed to “00”.

If the threshold voltage is lower than 0 V, for example, the state is regarded as “11”, and if the threshold voltage is equal to or higher than 0 V and lower than 1 V, for example, the state is regarded as “10”. Further, if the threshold voltage is equal to or higher than 1 V and lower than 2 V, for example, the state is regarded as “01” and if the threshold voltage is equal to or higher than 2 V, for example, the state is regarded as “00”.

Thus, four threshold voltages are used in order to store 2-bit data in one memory cell. In the actual device, since a variation occurs in the characteristics of the memory cells, the threshold voltages thereof also vary. If the variation is large, data cannot be distinguished and erroneous data may be read.

In the write method according to the present embodiment, first, variations in the typical threshold voltages as indicated by broken lines can be suppressed to narrow ranges as indicated by solid lines.

Tables 1 and 2 indicate voltages in the respective portions at the erase time, write time, read time and write verify time. In the tables 1 and 2, a case wherein the word line WL2 and the even-numbered bit line BLe are selected at the write time and read time is shown.

TABLE 1

| | | | First-step | | Second-step | | Write | | “10” | | “01” | | “00” | |
|---|---|---|---|---|---|---|---|---|---|---|---|---|---|---|
| | Erase | | Write | | Write | | Inhibition | | Read | | Read | | Read | |
| BLe | Floating | | 0 | V | 0.4 | V | Vdd | | H or L | | H or L | | H or L | |
| BLo | Floating | | Vdd | | Vdd | | Vdd | | 0 | V | 0 | V | 0 | V |
| SGD | Floating | | Vdd | | Vdd | | Vdd | | 4.5 | V | 4.5 | V | 4.5 | V |
| WL3 | 0 | V | 10 | V | 10 | V | 10 | V | 4.5 | V | 4.5 | V | 4.5 | V |
| WL2 | 0 | V | Vpgm | | Vpgm | | Vpgm | | 0 | V | 1 | V | 2 | V |
| WL1 | 0 | V | 0 | V | 0 | V | 0 | V | 4.5 | V | 4.5 | V | 4.5 | V |
| WL0 | 0 | V | 10 | V | 10 | V | 10 | V | 4.5 | V | 4.5 | V | 4.5 | V |
| SGS | Floating | | 0 | V | 0 | V | 0 | V | 4.5 | V | 4.5 | V | 4.5 | V |
| C-source | Floating | | 0 | V | 0 | V | 0 | V | 0 | V | 0 | V | 0 | V |
| C-p-well | 20 | V | 0 | V | 0 | V | 0 | V | 0 | V | 0 | V | 0 | V |

TABLE 2

| | “10” | | “10” | | “01” | | “01” | | “00” | | “00” | |
|---|---|---|---|---|---|---|---|---|---|---|---|---|
| | First-step | | Second-step | | First-step | | Second-step | | First-step | | Second-step | |
| | Write Verify | | Write Verify | | Write Verify | | Write Verify | | Write Verify | | Write Verify | |
| BLe | H or L | | H or L | | H or L | | H or L | | H or L | | H or L | |
| BLo | 0 | V | 0 | V | 0 | V | 0 | V | 0 | V | 0 | V |
| SGD | 4.5 | V | 4.5 | V | 4.5 | V | 4.5 | V | 4.5 | V | 4.5 | V |
| WL3 | 4.5 | V | 4.5 | V | 4.5 | V | 4.5 | V | 4.5 | V | 4.5 | V |
| WL2 | 0.2 | V | 0.4 | V | 1.2 | V | 1.4 | V | 2.2 | V | 2.4 | V |
| WL1 | 4.5 | V | 4.5 | V | 4.5 | V | 4.5 | V | 4.5 | V | 4.5 | V |
| WL0 | 4.5 | V | 4.5 | V | 4.5 | V | 4.5 | V | 4.5 | V | 4.5 | V |
| SGS | 4.5 | V | 4.5 | V | 4.5 | V | 4.5 | V | 4.5 | V | 4.5 | V |
| C-source | 0 | V | 0 | V | 0 | V | 0 | V | 0 | V | 0 | V |
| C-p-well | 0 | V | 0 | V | 0 | V | 0 | V | 0 | V | 0 | V |

(Erase)

At the erase time, the p-type cell well (C-p-well) 11 is set to 20 V and all of the word lines WL0 to WL3 of a selected block are set to 0 V. Electrons are discharged from the floating gate and the threshold voltage of the memory cell M is set to a negative voltage (“11” state). In this case, the word lines WL and bit lines BL of the non-selected block are set into an electrically floating state and set to approximately 20 V due to the capacitive coupling with the p-type cell well 11.

(Write)

At the write time, the voltage Vpgm of 14 V to 20 V is applied to the selected word line WL2. In this state, if the selected bit line BLe is set to 0 V, electrons are injected into the floating gate FG to rapidly raise the threshold voltage of the memory cell M (first-step write). In order to suppress the rising speed of the threshold voltage, the potential of the bit line BLe is raised t 0.4 V (second-step write). In order to inhibit the rise in the threshold voltage, the potential of the bit line BLe is set to power supply voltage Vdd (about 3 V) (write inhibition).

(Read)

At the read time, read voltage (0 V, 1 V, 2 V) is applied to the selected word line WL2. If the threshold voltage of the memory cell M is lower than the read voltage, for example, the bit line BLe and common source line C-source are electrically connected to each other and the potential of the bit line BLe is set to the relatively low level “L”. If the threshold voltage of the memory cell M is equal to or higher than the read voltage, for example, the bit line BLe and common source line C-source are isolated from each other and the potential of the bit line BLe maintains the relatively high level “H”. In order to detect whether or not the threshold voltage of the memory cell M is set higher than the state “10”, the read voltage is set to 0 V (“10” read). In order to detect whether or not the threshold voltage of the memory cell M is set higher than the state “01”, the read voltage is set to 1 V (“01” read). In order to detect whether or not the threshold voltage of the memory cell M is set higher than the state “00”, the read voltage is set to 2 V (“00” read).

The threshold voltage in the “10” state is set equal to or higher than 0.4 V so as to provide a read margin of 0.4 V with respect to the read voltage 0 V. For this purpose, in the case of writing “10”, a write verify operation is performed and if it is detected that the threshold voltage of the memory cell M has reached 0.4 V, a write inhibiting operation is performed to control the threshold voltage. Typically, in this case, only whether or not the threshold voltage has reached 0.4 V is detected. Therefore, as shown in FIG. 7, a relatively wide threshold voltage distribution range is provided (typical example).

On the other hand, in this example, whether the threshold voltage which is slightly lower than a target threshold voltage is reached or not is detected and the rising speed of the threshold voltage is suppressed in the second-step write process to narrow the threshold voltage distribution width as shown in FIG. 7 (in this example). This applies to the other states “01” and “00”.

The write verifying operation is performed by applying a verify voltage (0.2 V, 0.4 V, 1.2 V, 1.4 V, 2.2 V, 2.4 V) to the selected word line WL2. For example, if the threshold voltage of the memory cell M is lower than the verify voltage, the bit line BLe and common source line C-source are electrically connected to each other and the potential of the bit line BLe is set to the relatively low level “L”. For example, if the threshold voltage of the memory cell M is equal to or higher than the verify voltage, the bit line BLe and common source line C-source are isolated from each other and the potential of the bit line BLe maintains the relatively high level “H”. In order to detect whether or not the threshold voltage of the memory cell M is higher than 0.2 V, the write verify process is performed with the verify voltage set at 0.2 V (“10” first-step write verify). In order to detect whether or not the threshold voltage of the memory cell M is higher than 0.4 V, the write verify process is performed with the verify voltage set at 0.4 V (“10” second-step write verify). In order to detect whether or not the threshold voltage of the memory cell M is higher than 1.2 V, the write verify process is performed with the verify voltage set at 1.2 V (“01” first-step write verify). In order to detect whether or not the threshold voltage of the memory cell M is higher than 1.4 V, the write verify process is performed with the verify voltage set at 1.4 V (“01” second-step write verify). In order to detect whether or not the threshold voltage of the memory cell M is higher than 2.2 V, the write verify process is performed with the verify voltage set at 2.2 V (“00” first-step write verify). In order to detect whether or not the threshold voltage of the memory cell M is higher than 2.4 V, the write verify process is performed with the verify voltage set at 2.4 V (“00” second-step write verify).

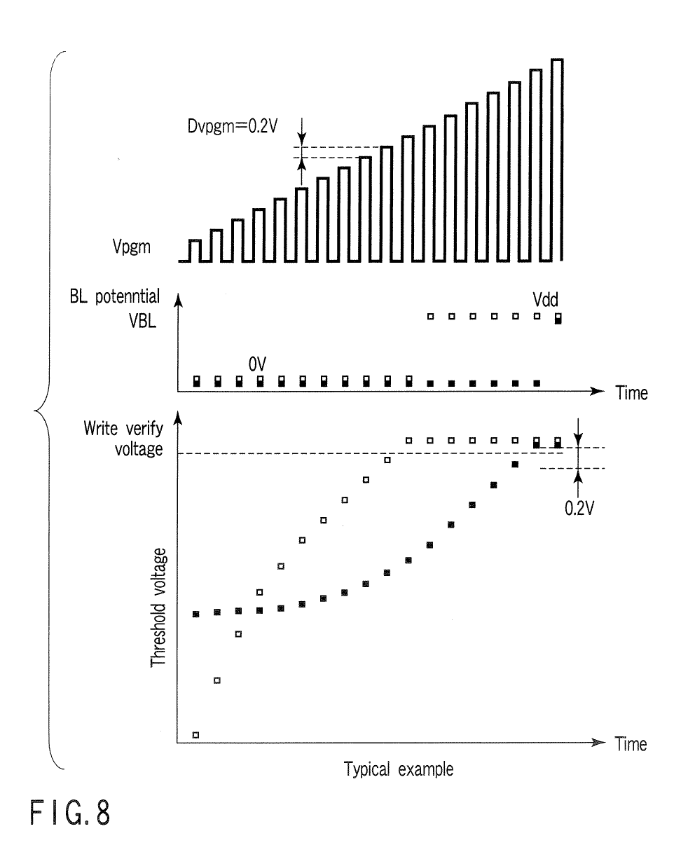

FIG. 8 is a diagram showing a typical write method and threshold voltage control process.

In FIG. 8, each void square indicates the threshold voltage of a memory cell into which data can be easily written and each black square indicates the threshold voltage of a memory cell into which data is difficult to be written. The above two memory cells store data items of the same page. Each of them is initially set in the erase state and has a negative threshold voltage.

As shown in FIG. 8, the write voltage Vpgm is divided into a plurality of pulses and is raised by 0.2 V for each pulse (Dvpgm=0.2 V), for example. If the voltage of the bit line BL which is the write control voltage is set to 0 V, the threshold voltage is raised at the same rate of 0.2 V/pulse as the voltage rise rate of the write voltage Vpgm after several pulses. The write verify process is performed after application of each write pulse, the bit line voltage of a memory cell whose threshold voltage has reached the write verify voltage is set to Vdd, and the write process is inhibited for each memory cell. Thus, the threshold voltage has the distribution width of 0.2 V.

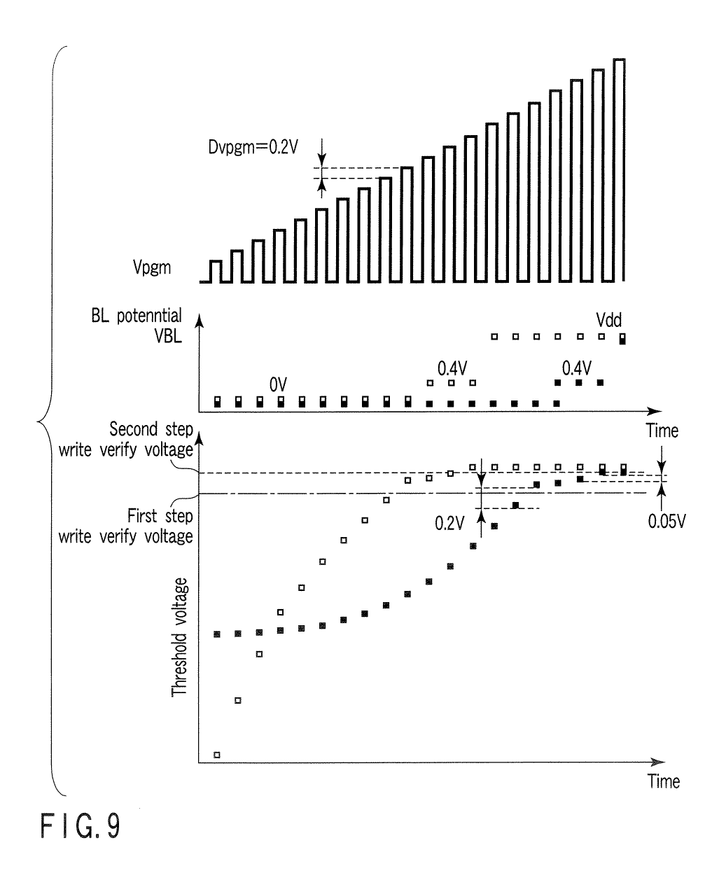

FIG. 9 is a diagram showing the write method of this example and threshold control process.

In FIG. 9, each void square indicates the threshold voltage of a memory cell into which data can be easily written and each black square indicates the threshold voltage of a memory cell into which data is difficult to be written. The above two memory cells store data items of the same page. Each of them is initially set in the erase state and has a negative threshold voltage.

As shown in FIG. 9, the write voltage Vpgm is divided into a plurality of pulses and is raised by 0.2 V for each pulse (Dvpgm=0.2 V), for example. If the voltage of the bit line BL which is the write control voltage is set to 0 V, the first-step write process is performed and the threshold voltage is raised at the same rate of 0.2 V/pulse as the voltage rise rate of the write voltage Vpgm after several pulses. The first-step and second-step write verify processes are performed after application of each write pulse, the bit line voltage of a memory cell whose threshold voltage has reached the first-step write verify voltage is set to 0.4 V, and the second-step write process is performed for each memory cell. Further, the bit line voltage of a memory cell whose threshold voltage has reached the second-step write verify voltage is set to Vdd and the write process is inhibited for each memory cell. Since the rise rate of the threshold voltage is suppressed to approximately 0 V/pulse to 0.05 V/pulse, for example, for several pulses after the second-step write process is started, the threshold voltage only has the distribution width of 0.05 V. Thus, the threshold voltage distribution width can be narrowed.

If the write pulse width is set to 20 μsec and each write verify time is set to 5 μsec, the write time produced by the typical write method is expressed as follows.
(20 μsec+5 μsec)×18 pulses=450 μsec

However, since it is necessary to reduce the voltage rise rate of the write voltage Vpgm to 0.05 V, that is, one-fourth in order to realize the threshold voltage distribution of 0.05 V, the write time becomes as follows.
450 μsec×4=1800 μsec

According to this example, as shown in FIG. 9, the threshold voltage distribution width of 0.05 V can be realized with the Vpgm rise rate of 0.2 V/pulse and the write time becomes as follows.
(20 μsec+5 μsec+5 μsec)×20 pulses=600 μsec

That is, in this example, the write time required for realizing the threshold voltage distribution of 0.05 V, which is the same as in the typical write method, can be reduced to one-third in comparison with the typical write method.

In this case, a “10” write process is performed by setting the first-step write verify voltage to the “10” first-step write verify voltage and setting the second-step write verify voltage to the “10” second-step write verify voltage.

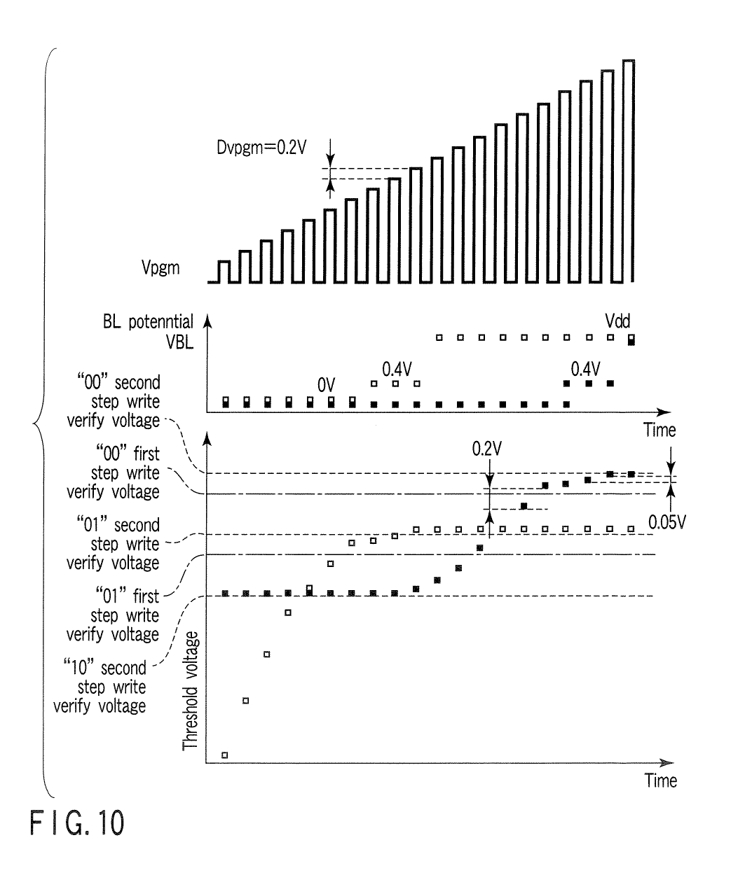

FIG. 10 is a diagram showing a method of writing upper page data into the same memory cell M in this example and a threshold control operation.

In FIG. 10, each void square indicates the threshold voltage of a memory cell into which data can be easily written and each black square indicates the threshold voltage of a memory cell into which data is difficult to be written. The above two memory cells store data items of respective columns of the same page. The memory cell indicated by the void square is initially set in the erase state, has a negative threshold voltage and is written into a “01” state. The memory cell indicated by the black square is initially set in the “10” state and is written into a “00” state.

As shown in FIG. 10, the write voltage Vpgm is divided into a plurality of pulses and is raised by 0.2 V for each pulse (Dvpgm=0.2 V), for example. If the voltage of the bit line BL which is the write control voltage is set to 0 V, the first-step write process is performed and the threshold voltage is raised at a rate of 0.2 V/pulse which is the same as the voltage rise rate of the write voltage Vpgm after several pulses. The “01” first-step and “01” second-step write verify processes are performed after application of each write pulse and then the “00” first-step and “00” second-step write processes are performed.

When it is detected that the threshold voltage of the memory cell indicated by the void square has reached the “01” first-step write verify voltage, the bit line voltage is set to 0.4 V and the second-step write state is set up. When it is detected that the threshold voltage of the memory cell indicated by the black square has reached the “00” first-step write verify voltage, the bit line voltage is set to 0.4 V and the second-step write state is set up.

When it is detected that the threshold voltage of the memory cell indicated by the void square has reached the “01” second-step write verify voltage, the bit line voltage is set to Vdd and the write operation is inhibited. Further, when it is detected that the threshold voltage of the memory cell indicated by the black square has reached the “00” second-step write verify voltage, the bit line voltage is set to Vdd and the write operation is inhibited.

For both of “01” and “00”, since the rise rate of the threshold voltage is suppressed to approximately 0 V/pulse to 0.05 V/pulse for a time period of several pulses after the second-step write state is set up, for example, the threshold voltage has only the distribution width of 0.05 V.

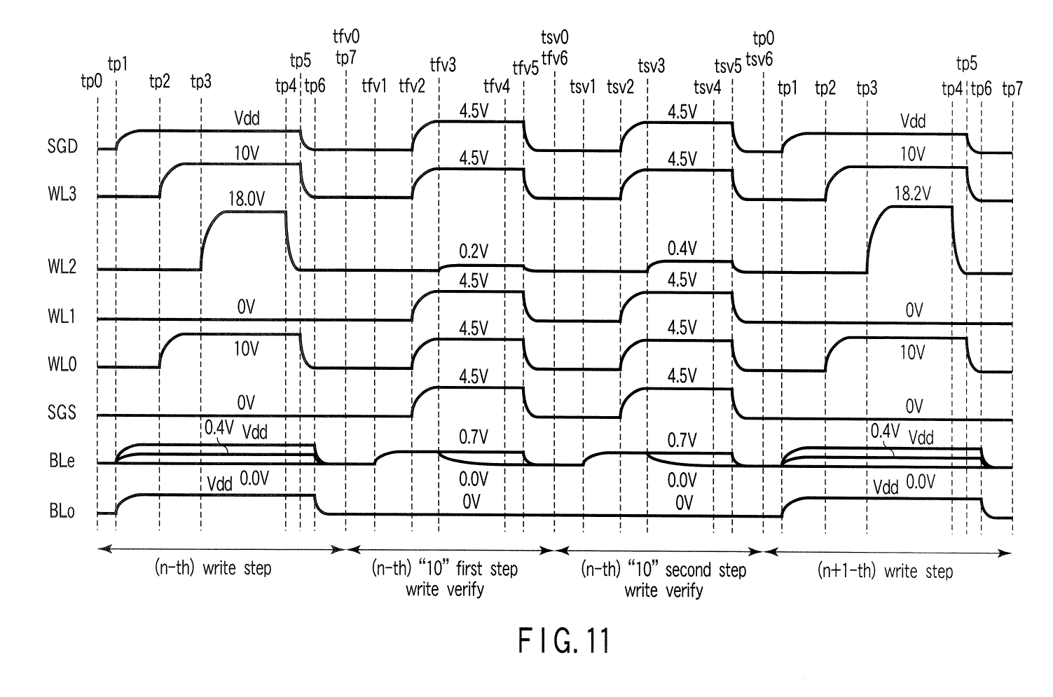

FIG. 11 is an operation waveform diagram showing waveforms at the write time of lower page data into the same memory cell M.

The write step is performed in a period from time tp0 to tp7 and a write pulse is applied. The “10” first-step write verify operation is performed in a period from time tfv0 to tfv6 and the “10” second-step write verify operation is performed in a period from time tsv0 to tsv6. In this example, a case wherein the word line WL and the even-numbered bit line BLe are selected is shown.

In the write step, the voltage of the bit line BLe which is the write control voltage is set to 0 V in the first-step write state, 0.4 V in the second-step write state and Vdd (for example, 2.5 V) in the write inhibition state.

At each write verify time, first, the bit line BLe is charged to 0.7 V. After this, when the voltage of the selected word line WL2 has reached the write verify voltage, the voltage of 0.7 V is maintained if the threshold voltage of the memory cell M has reached the write verify voltage. In this case, the voltage is lowered towards 0 V if the threshold voltage of the memory cell M does not reach the write verify voltage.

If the voltage of the bit line BLe is detected at the timing of time tfv4 or tsv4, whether or not the threshold voltage of the memory cell M has reached the write verify voltage can be detected. If the threshold voltage of the memory cell M has reached the write verify voltage, the detection result is “pass”.

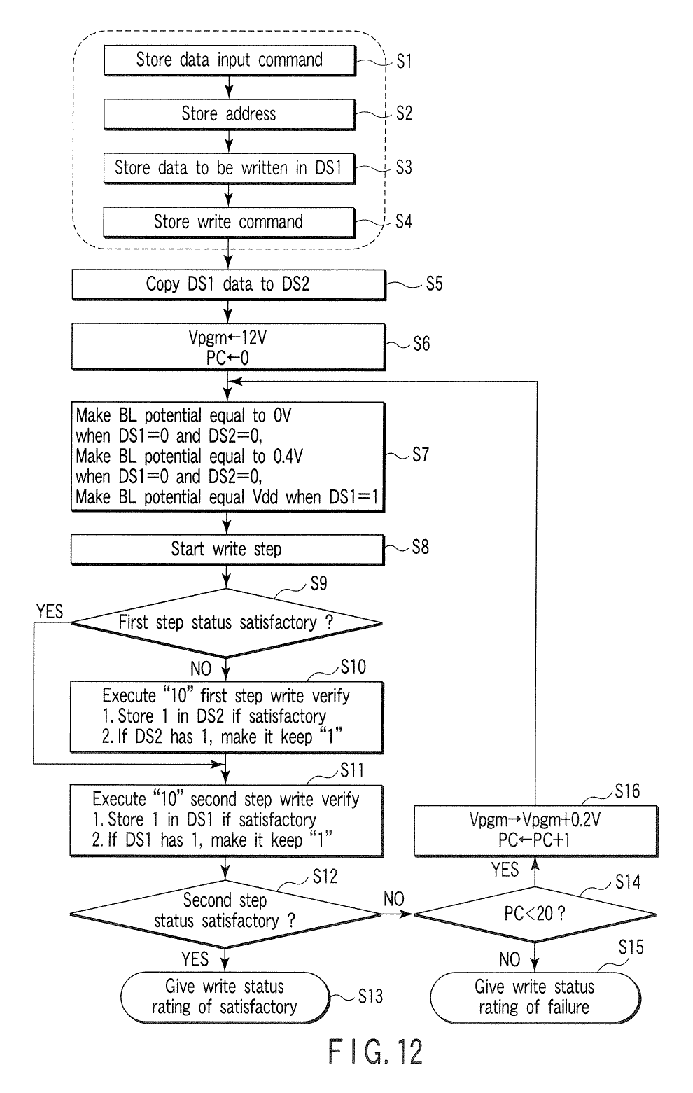

FIG. 12 is a flow chart showing an algorithm of writing lower page data into the same memory cell M.

First, for example, the command interface 7 receives a data input command from the host and sets the data input command in the state machine 8 (S1).

Next, for example, the command interface 7 receives address data from the host and sets an address to select a write page in the state machine 8 (S2).

Next, for example, the data input/output buffer 6 receives write data of one page and sets corresponding write data into the respective data storage sections DS1 (S3).

Next, for example, the command interface 7 receives a write command issued from the host and sets the write command in the state machine 8 (S4). After the write command is set, the steps S5 to S16 are automatically started in the internal portion by the state machine 8.

Next, data of each data storage section DS1 is copied into a corresponding one of the data storage sections DS2 (S5). After this, the initial value of the write voltage Vpgm is set to 12 V and the write counter PC is set to “0” (S6).

If data of the data storage section DS1 is “0” and data of the data storage section DS2 is “0”, it is determined that the first-step write state is set. Therefore, the voltage of the bit line which is the write control voltage is set at 0 V.

If data of the data storage section DS1 is “0” and data of the data storage section DS2 is “1”, it is determined that the second-step write state is set. Therefore, the voltage of the bit line which is the write control voltage is set at 0.4 V.

If data of the data storage section DS1 is “1”, it is determined that the write inhibition state is set. Therefore, the voltage of the bit line which is the write control voltage is set at Vdd (S7).

Next, write pulses are applied to the memory cells of one page by use of the set write voltage Vpgm and write control voltage. That is, the write step is performed (S8).

Whether or not data items of all of the data storage sections DS2 are “1” is detected and if all of the data items are “1”, it is determined that the first-step status is “pass”, and if not, it is determined that the above status is not “pass” (S9). As will be described later, if data items of all of the data storage sections DS2 are “1”, it is determined that no memory cell is subjected to the first-step write operation in the preceding write step (S8).

If the first-step status is not “pass”, the “10” first-step write verify operation is started (S10). Data of the data storage section DS2 corresponding to the memory cell in which the detection result is set to “pass” among the memory cells of one page is changed from “0” to “1”. If data of the data storage section DS2 is “1”, the “1” data is maintained.

If the first-step status is “pass” or when the “10” first-step write verify operation is terminated, the “10” second-step write verify operation is started (S11). Data of the data storage section DS1 corresponding to the memory cell in which the detection result is set to “pass” among the memory cells of one page is changed from “0” to “1”. If data of the data storage section DS1 is “1”, the “1” data is maintained.

After the “10” second-step write verify operation, whether or not data items of all of the data storage sections DS1 are “1” is detected and if all of the data items are “1”, it is determined that the second-step status is “pass”, and if not, it is determined that the above status is not “pass” (S12).

If the second-step status is “pass”, it is determined that the write operation is correctly terminated, the write status is set to “pass” and the write operation is terminated (S13).

If the second-step status is not “pass”, the write counter PC is checked (S14) and if the count thereof is equal to or larger than 20, it is determined that data could not be correctly written, the write status is set to “fail” and the write operation is terminated (S15).

If the count of the write counter PC is smaller than 20, the count of the write counter PC is incremented by one, the setting value of the write voltage Vpgm is increased by 0.2 V (S16) and the process is returned to the write step S8 again after the step S7 is performed.

Table 3 shows the relation between data items before and after the “10” first-step write verify operation of the data storage sections DS1 and DS2 in the algorithm of writing lower page data into the same memory cell M shown in FIG. 12 and the threshold voltage of a corresponding memory cell.

TABLE 3

Threshold voltage
Vt of memory cell

| | | Lower than | Not lower |
|---|---|---|---|
| | | 0.2 V | than 0.2 V |
| Data DS1/DS2 | 0/0 | 0/0 | 0/0 |
| before nth “10” | 0/1 | 0/1 | 0/1 |
| first-step | 1/1 | 1/1 | 1/1 |
| write verify | | | |

Data DS1/DS2 after the nth “10” first-step write verify

As shown in table 3, a value which can be set in the data storage sections DS1 and DS2 before the nth “10” first-step write verify operation is 0/0, 0/1 or 1/1.

0/0 indicates that the threshold voltage of the memory cell does not reach the “10” first-step write verify voltage until the (n-l)th write step.

0/1 indicates that the threshold voltage of the memory cell has reached the “10” first-step write verify voltage, but does not reach the “10” second-step write verify voltage until the (n-1)th write step.

1/1 indicates that the threshold voltage of the memory cell has reached the “10” second-step write verify voltage until the (n-1)th write step.

Since there occurs no possibility that the threshold voltage of the memory cell has reached the “10” second-step write verify voltage, but does not reach the “10” first-step write verify voltage until the (n-1)th write step, the state of 1/0 is not provided in this example.

A value which can be set in the data storage sections DS1 and DS2 before the first “10” first-step write verify operation is 0/0 or 1/1.

Since the detection result in the “10” first-step write verify operation is not “pass” if the threshold voltage of the memory cell does not reach 0.2 V which is the “10” first-step write verify voltage in the nth write step, data of the data storage section DS2 is kept unchanged. Since the detection result in the “10” first-step write verify operation is “pass” if the threshold voltage of the memory cell reaches 0.2 V which is the “10” first-step write verify voltage in the nth write step, data of the data storage section DS2 is changed to “1”. Data of the data storage section DS2 which is “1” is kept unchanged irrespective of the threshold voltage of the memory cell.

Table 4 shows the relation between data items before and after the “10” second-step write verify operation of the data storage sections DS1 and DS2 in the algorithm of writing lower page data into the same memory cell M shown in FIG. 12 and the threshold voltage of a corresponding memory cell.

TABLE 4

Threshold voltage
Vt of memory cell

| | | Lower than | Not lower |
|---|---|---|---|
| | | 0.4 V | than 0.4 V |
| Data DS1/DS2 | 0/0 | 0/0 | — |
| before nth “10” | 0/1 | 0/1 | 1/1 |
| second-step | 1/1 | 1/1 | 1/1 |
| write verify | | | |

Data DS1/DS2 after the nth “10” second-step write verify

As shown in table 4, a value which can be set in the data storage sections DS1 and DS2 before the nth “10” second-step write verify operation is 0/0, 0/1 or 1/1.

0/0 indicates that the threshold voltage of the memory cell does not reach the “10” first-step write verify voltage after the nth write step. 0/1 indicates that the threshold voltage of the memory cell has reached the “10” first-step write verify voltage until the nth write step, but the threshold voltage of the memory cell does not reach the “10” second-step write verify voltage until the (n-1)th write step. 1/1 indicates that the threshold voltage of the memory cell has reached the “10” second-step write verify voltage until the (n-1)th write step.

Since there occurs no possibility that the threshold voltage of the memory cell has reached the “10” second-step write verify voltage until the (n-1)th write step, but the threshold voltage of the memory cell does not reach the “10” first-step write verify voltage until the nth write step, the state of 1/0 is not provided in this example.

Since the detection result in the “10” second-step write verify operation is not “pass” if the threshold voltage of the memory cell does not reach 0.4 V, which is the “10” second-step write verify voltage in the nth write step, data of the data storage section DS1 is kept unchanged. Since the detection result in the “10” second-step write verify operation is “pass” if the threshold voltage of the memory cell reaches 0.4 V which is the “10” second-step write verify voltage in the nth write step, data of the data storage section DS1 is changed to “1”. Data of the data storage section DS1 which is “1” is kept unchanged irrespective of the threshold voltage of the memory cell. 0/0 is not changed by the “10” second-step write verify operation.

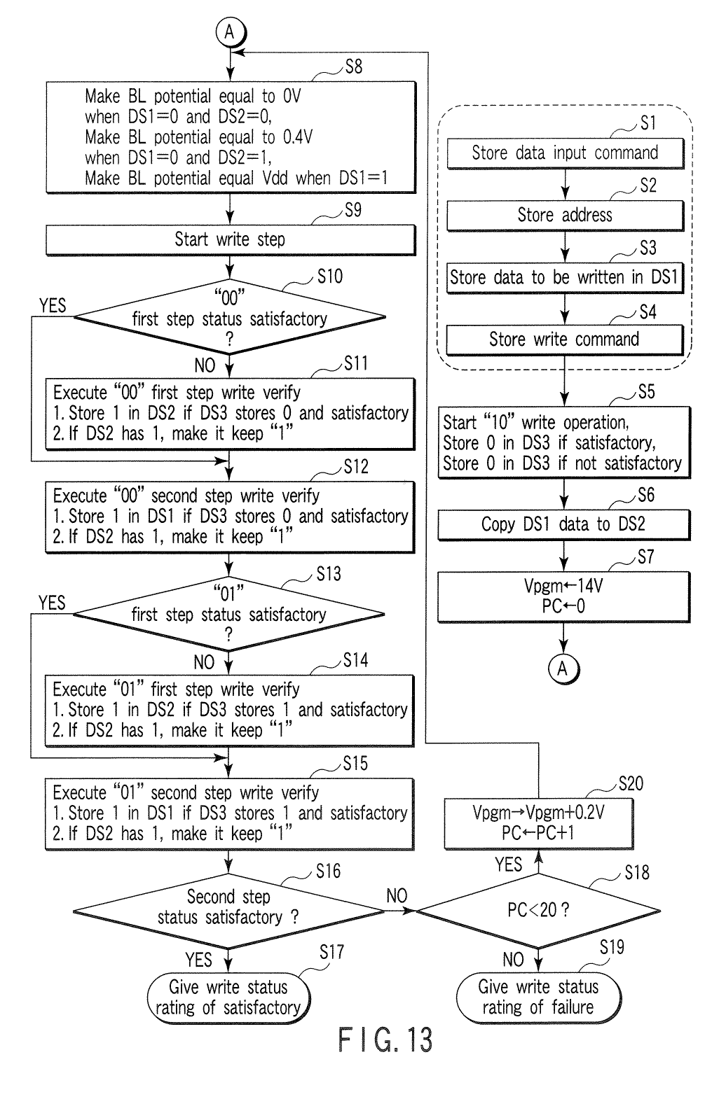

FIG. 13 is a diagram showing a write algorithm of upper page data to the same memory cell M.

First, for example, the command interface 7 receives a data input command from the host and sets the data input command in the state machine 8 (S1).

Next, for example, the command interface 7 receives address data from the host and sets an address to select a write page in the state machine 8 (S2).

Then, for example, the data input/output buffer 6 receives write data of one page and sets corresponding write data into the respective data storage sections DS1 (S3).

Next, for example, the command interface 7 receives a write command issued from the host and sets the write command in the state machine 8 (S4). After the write command is set, steps S5 to S20 are automatically started in the internal portion by the state machine 8.

First, the “10” read operation is started (S5). In the case of “pass” (when the memory cell is “10”), “0” is set into a corresponding one of the data storage sections DS3. If it is not “pass”, “1” is set into a corresponding one of the data storage sections DS3.

Next, data of each data storage section DS1 is copied into a corresponding one of the data storage sections DS2 (S6). After this, the initial value of the write voltage Vpgm is set to 14 V and the write counter PC is set to “0” (S7).

If data of the data storage section DS1 is “0” and data of the data storage section DS2 is “0”, it is determined that the first-step write state is set. Therefore, the voltage of the bit line which is the write control voltage is set at 0 V.

If data of the data storage section DS1 is “0” and data of the data storage section DS2 is “1”, it is determined that the second-step write state is set. Therefore, the voltage of the bit line which is the write control voltage is set at 0.4 V.

If data of the data storage section DS1 is “1”, it is determined that the write inhibition state is set. Therefore, the voltage of the bit line which is the write control voltage is set at Vdd (S8).

Next, write pulses are applied to the memory cells of one page by use of the set write voltage Vpgm and write control voltage. That is, the write step is performed (S9).

Whether or not data items of all of the data storage sections DS2 in the data storage circuit 16 in which “0” is stored in the data storage section DS3 are “1” is detected. Then, if all of the data items are “1”, it is determined that the “00” first-step status is “pass”, and if not, it is determined that the above status is not “pass” (S10). As will be described later, if data items of all of the data storage sections DS2 are “1”, there is no memory cell which is subjected to the “00” first-step write operation in the preceding write step (S9).

If the “00” first-step status is not “pass”, the “00” first-step write verify operation is started (S11). Data of the data storage section DS2 corresponding to the memory cell in which the detection result is set to “pass” among the memory cells of one page and lying in the data storage circuit 16 in which data of the data storage section DS3 is “0” is changed from “0” to “1”. If data of the data storage section DS2 is “1”, the “1” data is maintained.

If the “00” first-step status is “pass” or when the “00” first-step write verify operation is terminated, the “00” second-step write verify operation is started (S12). Data of the data storage section DS1 corresponding to the memory cell in which the detection result is set to “pass” among the memory cells of one page and lying in the data storage circuit 16 in which data of the data storage section DS3 is “0” is changed from “0” to “1”. If data of the data storage section DS1 is “1”, the “1” data is maintained.

Next, whether data items of all of the data storage sections DS2 in the data storage circuit 16 in which data “1” is stored in the data storage section DS3 are “1” or not is detected. Then, if all of the data items are “1”, it is determined that the “01” first-step status is “pass”, and if not, it is determined that the above status is not “pass” (S13). As will be described later, if data items of all of the data storage sections DS2 are “1”, there is no memory cell which is subjected to the “01” first-step write operation in the preceding write step (S9).

If the “01” first-step status is not “pass”, the “01” first-step write verify operation is started (S14). Data of the data storage section DS2 corresponding to the memory cell in which the detection result is set to “pass” among the memory cells of one page and lying in the data storage circuit 16 in which data of the data storage section DS3 is “1” is changed from “0” to “1”. If data of the data storage section DS2 is “1”, the “1” data is maintained.

If the “01” first-step status is set to “pass” or the “01” write verify operation is terminated, the “01” second-step write verify operation is started (S15). Data of the data storage section DS1 corresponding to the memory cell in which the detection result is set to “pass” among the memory cells of one page and lying in the data storage circuit 16 in which data of the data storage section DS3 is “1” is changed from “0” to “1”. If data of the data storage section DS1 is “1”, the “1” data is maintained.

After the “01” second-step write verify operation, whether or not data items of all of the data storage sections DS1 are “1” is detected. Then, if all of the data items are “1”, it is determined that the second-step status is “pass”, and if not, it is determined that the above status is not “pass” (S16). If the second-step status is “pass”, it is determined that the write operation is correctly performed, the write status is set to “pass” and the write operation is terminated (S17). If the second-step status is not “pass”, the write counter PC is checked (S18). Then, if the count thereof is not smaller than 20, it is determined that the write operation could not be correctly performed, the write status is set to “fail” and the write operation is terminated (S19). If the count of the write counter PC is smaller than 20, the count of the write counter PC is incremented by one, the setting value of the write voltage Vpgm is increased by 0.2 V (S20) and the process is returned to the write step S9 again after the step S8 is performed.

Table 5 shows the relation between data items before and after the “01” first-step write verify operation of the data storage sections DS1, DS2 and DS3 in the algorithm of writing upper page data to the same memory cell M shown in FIG. 12 and the threshold voltage of a corresponding memory cell.

TABLE 5

Threshold voltage
Vt of memory cell

| | | Lower than | Not lower |
|---|---|---|---|
| | | 1.2 V | than 1.2 V |
| Data | 0/0/1 | 0/0/1 | 0/1/1 |
| DS1/DS2/DS3 | 0/1/1 | 0/1/1 | 0/1/1 |
| before nth “01” | 1/1/1 | 1/1/1 | 1/1/1 |
| first-step | 0/0/0 | 0/0/0 | 0/0/0 |
| write verify | 0/1/0 | 0/1/0 | 0/1/0 |
| | 1/1/0 | 1/1/0 | 1/1/0 |

Data DS1/DS2/DS3 after the nth “01” first-step write verify

As shown in table 5, a value which can be set in the data storage sections DS1, DS2 and DS3 before the nth “01” first-step write verify operation is 0/0/1, 0/1/1, 1/1/1, 0/0/0, 0/1/0 or 1/1/0.

0/0/1 indicates that the threshold voltage of the memory cell does not reach the “01” first-step write verify voltage until the (n-1)th write step.

0/1/1 indicates that the threshold voltage of the memory cell has reached the “01” first-step write verify voltage, but does not reach the “01” second-step write verify voltage until the (n-1)th write step.

1/1/1 indicates that the threshold voltage of the memory cell has reached the “01” second-step write verify voltage until the (n-1)th write step.

Since there occurs no possibility that the threshold voltage of the memory cell has reached the “01” second-step write verify voltage, but does not reach the “01” first-step write verify voltage until the (n-1)th write step, the state of 1/0/1 is not provided in this example.

The detection result in the “01” first-step write verify operation is not “pass” if the threshold voltage of the memory cell does not reach 1.2 V which is the “01” first-step write verify voltage in the nth write step. In this case, data of the data storage section DS2 is kept unchanged.

The detection result in the “01” first-step write verify operation is “pass” if the threshold voltage of the memory cell has reached 1.2 V which is the “01” first-step write verify voltage in the nth write step. In this case, data of the data storage section DS2 is changed to “1”. Data of the data storage section DS2 which is “1” is kept unchanged irrespective of the threshold voltage of the memory cell. Further, 0/0/0, 0/1/0, 1/1/0 are not objects to be subjected to the “01” first-step write verify operation, and therefore, they are kept unchanged.

Table 6 shows the relation between data items before and after the “01” second-step write verify operation of the data storage sections DS1, DS2 and DS3 in the algorithm of writing upper page data to the same memory cell M shown in FIG. 13 and the threshold voltage of a corresponding memory cell.

TABLE 6

Threshold voltage
Vt of memory cell

| | | Lower than | Not lower |
|---|---|---|---|
| | | 1.4 V | than 1.4 V |
| Data | 0/0/1 | 0/0/1 | — |
| DS1/DS2/DS3 | 0/1/1 | 0/1/1 | 1/1/1 |
| before nth “01” | 1/1/1 | 1/1/1 | 1/1/1 |
| second-step | 0/0/0 | 0/0/0 | 0/0/0 |
| write verify | 0/1/0 | 0/1/0 | 0/1/0 |
| | 1/1/0 | 1/1/0 | 1/1/0 |

Data DS1/DS2/DS3 after the nth “01” second-step write verify

As shown in table 6, a value which can be set in the data storage sections DS1, DS2 and DS3 before the nth “01” second-step write verify operation is 0/0/1, 0/1/1, 1/1/1, 0/0/0, 0/1/0 or 1/1/0.

0/0/1 indicates that the threshold voltage of the memory cell does not reach the “01” first-step write verify voltage after the nth write step.

0/1/1 indicates that the threshold voltage of the memory cell has reached the “01” first-step write verify voltage until the nth write step, but the threshold voltage of the memory cell does not reach the “01” second-step write verify voltage until the (n-1)th write step.

1/1/1 indicates that the threshold voltage of the memory cell has reached the “01” second-step write verify voltage until the (n-1)th write step.

The detection result in the “01” second-step write verify operation is not “pass” if the threshold voltage of the memory cell does not reach 1.4 V which is the “01” second-step write verify voltage in the nth write step. In this case, data of the data storage section DS1 is kept unchanged.

The detection result in the “01” second-step write verify operation is “pass” if the threshold voltage of the memory cell has reached 1.4 V which is the “01” second-step write verify voltage in the nth write step. In this case, data of the data storage section DS1 is changed to “1”. Data of the data storage section DS1 which is “1” is kept unchanged irrespective of the threshold voltage of the memory cell. 0/0/1 is not changed by the “01” second-step write verify operation. Further, 0/0/0, 0/1/0, 1/1/0 are not objects to be subjected to the “01” second-step write verify operation, and therefore, they are kept unchanged.

Table 7 shows the relation between data items before and after the “00” first-step write verify operation of the data storage sections DS1, DS2 and DS3 in the algorithm of writing upper page data to the same memory cell M shown in FIG. 13 and the threshold voltage of a corresponding memory cell.

TABLE 7

Threshold voltage
Vt of memory cell

| | | Lower than | Not lower |
|---|---|---|---|
| | | 2.2 V | than 2.2 V |
| Data | 0/0/1 | 0/0/1 | — |
| DS1/DS2/DS3 | 0/1/1 | 0/1/1 | — |
| before nth “00” | 1/1/1 | 1/1/1 | — |
| first-step | 0/0/0 | 0/0/0 | 0/1/0 |
| write verify | 0/1/0 | 0/1/0 | 0/1/0 |
| | 1/1/0 | 1/1/0 | 1/1/0 |

Data DS1/DS2/DS3 after the nth “00” first-step write verify

As shown in table 7, a value which can be set in the data storage sections DS1, DS2 and DS3 before the nth “00” first-step write verify operation is 0/0/1, 0/1/1, 1/1/1, 0/0/0, 0/1/0 or 1/1/0.

0/0/0 indicates that the threshold voltage of the memory cell does not reach the “00” first-step write verify voltage until the (n-1)th write step.

0/1/0 indicates that the threshold voltage of the memory cell has reached the “00” first-step write verify voltage until the (n-1)th write step, but does not reach the “00” second-step write verify voltage.

1/1/0 indicates that the threshold voltage of the memory cell has reached the “00” second-step write verify voltage until the (n-1)th write step.

Since there occurs no possibility that the threshold voltage of the memory cell has reached the “00” second-step write verify voltage until the (n-1)th write step, but does not reach the “00” first-step write verify voltage, the state of 1/0/0 is not provided in this example.

The detection result in the “00” first-step write verify operation is not “pass” if the threshold voltage of the memory cell does not reach 2.2 V, which is the “00” first-step write verify voltage in the nth write step. In this case, data of the data storage section DS2 is kept unchanged.

Since the detection result in the “00” first-step write verify operation is “pass” if the threshold voltage of the memory cell has reached 2.2 V, which is the “00” first-step write verify voltage in the nth write step, data of the data storage section DS2 is changed to “1”. Data of the data storage section DS2 which is “1” is kept unchanged irrespective of the threshold voltage of the memory cell. Further, 0/0/1, 0/1/1, 1/1/1 are not objects to be subjected to the “01” first-step write verify operation and are kept unchanged.

Table 8 shows the relation between data items before and after the “00” second-step write verify operation of the data storage sections DS1, DS2 and DS3 in the write algorithm of upper page data to the same memory cell M shown in FIG. 12 and the threshold voltage of a corresponding memory cell.

TABLE 8

Threshold voltage
Vt of memory cell

| | | Lower than | Not lower |
|---|---|---|---|
| | | 2.4 V | than 2.4 V |
| Data | 0/0/1 | 0/0/1 | — |
| DS1/DS2/DS3 | 0/1/1 | 0/1/1 | — |
| before nth “00” | 1/1/1 | 1/1/1 | — |
| second-step | 0/0/0 | 0/0/0 | — |
| write verify | 0/1/0 | 0/1/0 | 1/1/0 |
| | 1/1/0 | 1/1/0 | 1/1/0 |

Data DS1/DS2/DS3 after the nth “00” second-step write verify

As shown in table 8, a value which can be set in the data storage sections DS1, DS2 and DS3 before the nth “00” second-step write verify operation is 0/0/1, 0/1/1, 1/1/1, 0/0/0, 0/1/0 or 1/1/0.

0/0/0 indicates that the threshold voltage of the memory cell does not reach the “00” first-step write verify voltage after the nth write step.

0/1/0 indicates that the threshold voltage of the memory cell has reached the “00” first-step write verify voltage until the nth write step, but the threshold voltage of the memory cell does not reach the

“00” second-step write verify voltage until the (n-1)th write step.

1/1/0 indicates that the threshold voltage of the memory cell has reached the “00” second-step write verify voltage until the (n-1)th write step.

Since there occurs no possibility that the threshold voltage of the memory cell has reached the “00” second-step write verify voltage until the (n-1)th write step, but the threshold voltage of the memory cell does not reach the “00” first-step write verify voltage until the nth write step, the state of 1/0/0 is not provided in this example.

The detection result in the “00” second-step write verify operation is not “pass” if the threshold voltage of the memory cell does not reach 2.4 V which is the “00” second-step write verify voltage in the nth write step. In this case, data of the data storage section DS1 is kept unchanged.

The detection result in the “00” second-step write verify operation is “pass” if the threshold voltage of the memory cell has reached 2.4 V which is the “00” second-step write verify voltage in the nth write step. In this case, data of the data storage section DS1 is changed to “1”. Data of the data storage section DS1 which is “1” is kept unchanged irrespective of the threshold voltage of the memory cell. 0/0/0 is not changed by the “00” second-step write verify operation. Further, 0/0/1, 0/1/1, 1/1/1 are not objects to be subjected to the “00” second-step write verify operation, and therefore, they are kept unchanged.

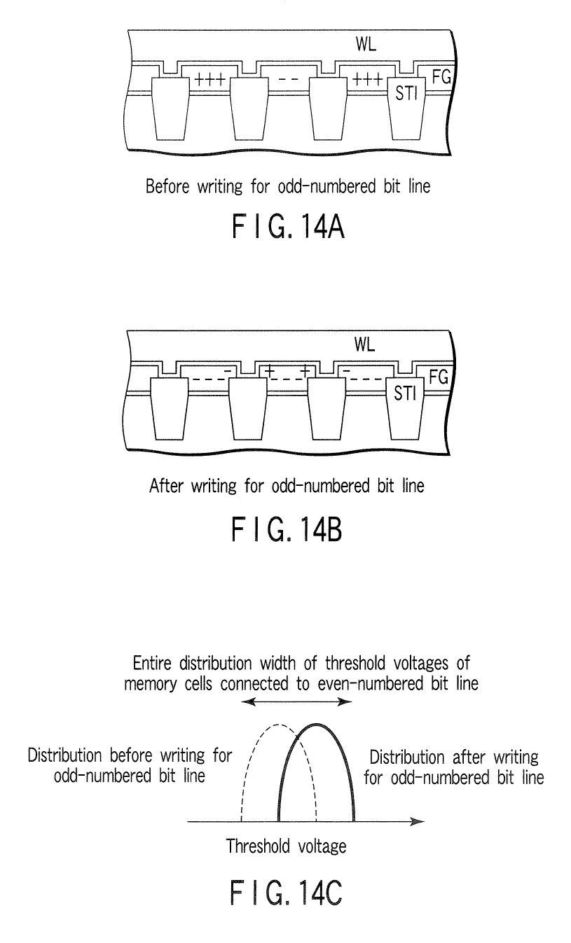

FIGS. 14A to 14C are views and a diagram showing states caused by miniaturization of the processing dimensions of a multi-level flash memory.

FIG. 14A shows a state of charges of the floating gate FG after the write operation is performed for the even-numbered bit line BLe after erasing.

Electrons (−) are charged in the floating gate FG of the memory cell M subjected to the write operation. After this, if the write operation is performed for the odd-numbered bit line BLo, a variation occurs in the state of the floating gate FG of the memory cell M connected to the even-numbered bit line BLe as shown in FIG. 14B. The potential of the even-numbered memory cell M is lowered by the electrostatic capacitive coupling between the adjacent floating gates FG and the threshold voltage is increased as shown in FIG. 14C.

In the above conditions, the technique for narrowing the threshold voltage distribution width becomes extremely important in the future.

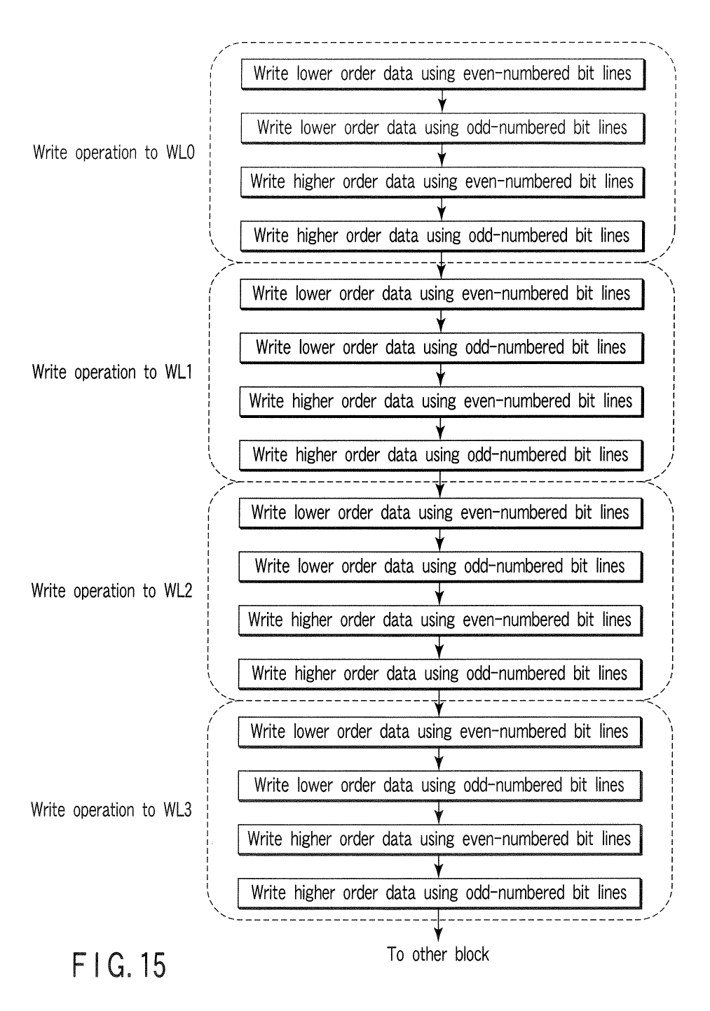

FIG. 15 is a diagram showing a write order in the blocks.

First, a word line WL0 is selected and lower data is written into one page configured by the memory cells M connected to the even-numbered bit lines. Then, lower data is written to one page configured by the memory cells M connected to the odd-numbered bit lines. Thirdly, upper data is written to one page configured by the memory cells M connected to the even-numbered bit lines and, finally, upper data is written to one page configured by the memory cells M connected to the odd-numbered bit lines. After this, the word lines WL1, WL2, WL3 are selected and the write operation is performed in the same manner.

Thus, interference between the adjacent floating gates can be suppressed to minimum. That is, the state of the memory cell M to be subjected to the write operation later is not transited from “11” to “00” even if the state thereof is transited from “11” to “10”, from “11” to “01” or from “10” to “00”. Transition from “11” to “00” causes the threshold voltage of the adjacent memory cell to be most extremely raised.

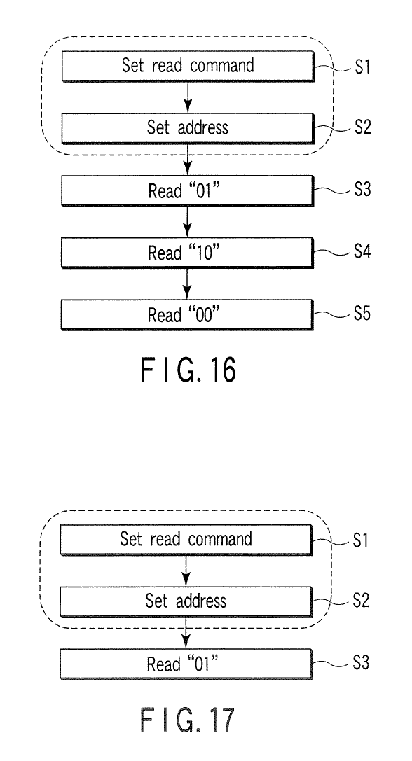

FIG. 16 is a diagram showing a read algorithm of lower page data of the same memory cell M.

First, for example, the command interface 7 receives a read command from the host and sets the read command in the state machine 8 (S1). Next, the command interface 7 receives address data from the host and sets an address to select a read page in the state machine 8 (S2). Thus, the address is set and steps S3 to S5 are automatically started in the internal portion by the state machine 8.

First, the “01” read operation is started (S3). The result of reading is stored in a corresponding data storage section DS3. Next, the “10” read operation is started (S4) and the result of reading is stored in a corresponding data storage section DS2. Finally, the “00” read operation is started (S5) and lower page data is subjected to the logical operation based on data of the data storage sections DS2 and DS3 corresponding to the read result and stored in a corresponding data storage section DS1. The data of the data storage section DS1 is externally output.

FIG. 17 is a diagram showing a read algorithm of upper page data of the same memory cell M.

First, for example, the command interface 7 receives a read command from the host and sets the read command in the state machine 8 (S1). Next, the command interface 7 receives address data from the host and sets an address to select a read page in the state machine 8 (S2). Thus, the address is set and step S3 is automatically started in the internal portion by the state machine 8.

The “01” read operation is started (S3). The read result is upper page data and is stored in a corresponding data storage section DS1. The data of the data storage section DS1 is externally output.

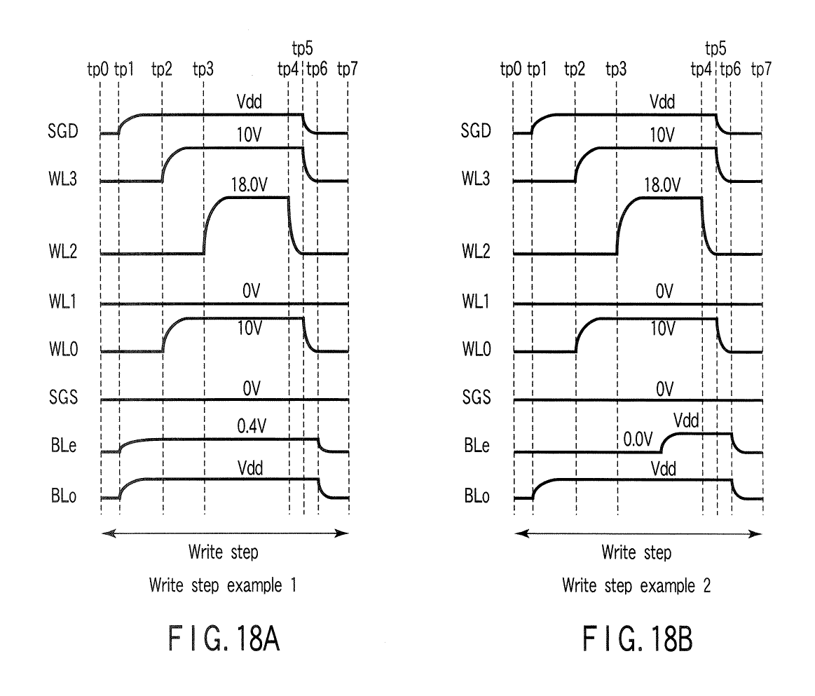

FIG. 18A is an operation waveform diagram showing a write step example 1 shown in FIG. 11. FIG. 18B is an operation waveform diagram showing a write step example 2.

As shown in FIG. 18B, voltage VBL of the bit line BL which is the write control voltage is not set to 0.4 V, but is set and kept at 0 V for a preset period by applying the write voltage Vpgm to a selected word line WL and is then set at Vdd to inhibit the write operation. As a result, the effective write pulse width is reduced, a rise in the threshold voltage is suppressed and the same effect as that obtained when the voltage VBL of the bit line BL which is the write control voltage is set to 0.4 V can be obtained.

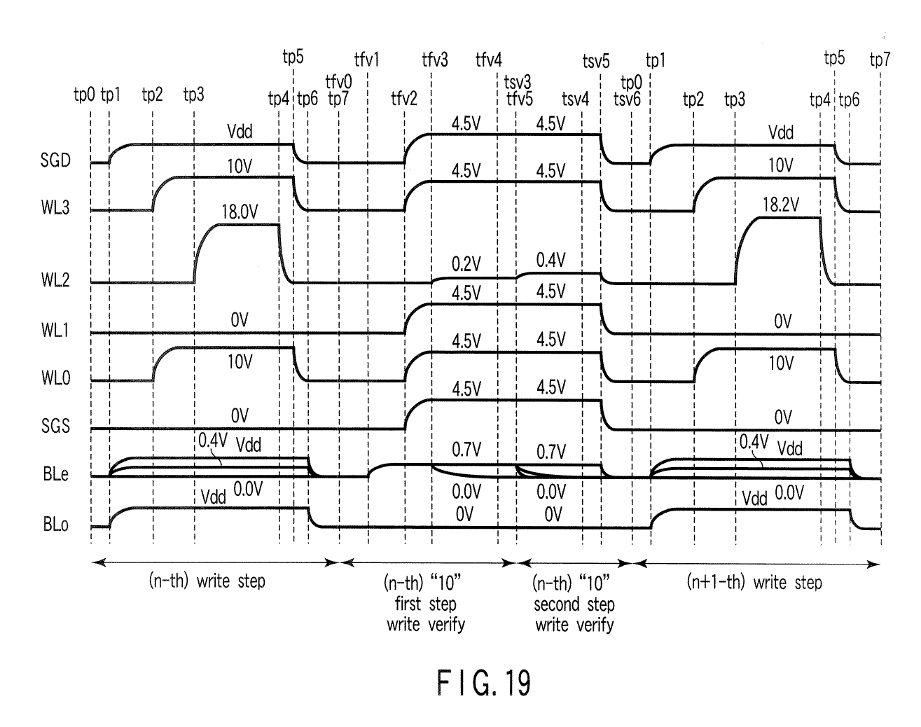

FIG. 19 is an operation waveform diagram showing a modification of the write verify operation shown in FIG. 11.

As shown in FIG. 19, at the time of first-step write verify, first, the bit line BLe is charged to 0.7 V. After this, when the potential of the selected word line WL2 reaches the first-step write verify voltage or if the threshold voltage of the memory cell M reaches the first-step write verify voltage, 0.7 V is maintained. Further, if the threshold voltage of the memory cell M does not reach the first-step write verify voltage, the voltage is lowered towards 0 V. If the voltage of the bit line BLe is detected at the timing tfv4, whether or not the threshold voltage of the memory cell M reaches the first-step write verify voltage can be detected. If the threshold voltage of the memory cell M reaches the write verify voltage, the detection result is “pass”.

After this, the voltage of the selected word line WL2 is switched from the first-step write verify voltage to the second-step write verify voltage at the timing tfv5 or at the same timing tsv3. If the threshold voltage of the memory cell M reaches the second-step write verify voltage, 0.7 V is maintained. Further, if the threshold voltage of the memory cell M does not reach the second-step write verify voltage, the voltage is lowered towards 0 V. If the voltage of the bit line BLe is detected at the timing tsv4, whether or not the threshold voltage of the memory cell M reaches the second-step write verify voltage can be detected. If the threshold voltage of the memory cell M reaches the write verify voltage, the detection result is “pass”.

Thus, the charging time of the bit line at the time of second-step write verify can be omitted and the write operation can be more rapidly performed. The “01” or “00” first-step or second-step write verify operation can be performed in the same manner simply by changing the write verify voltage.

The semiconductor integrated circuit device according to this example further includes the following configuration.

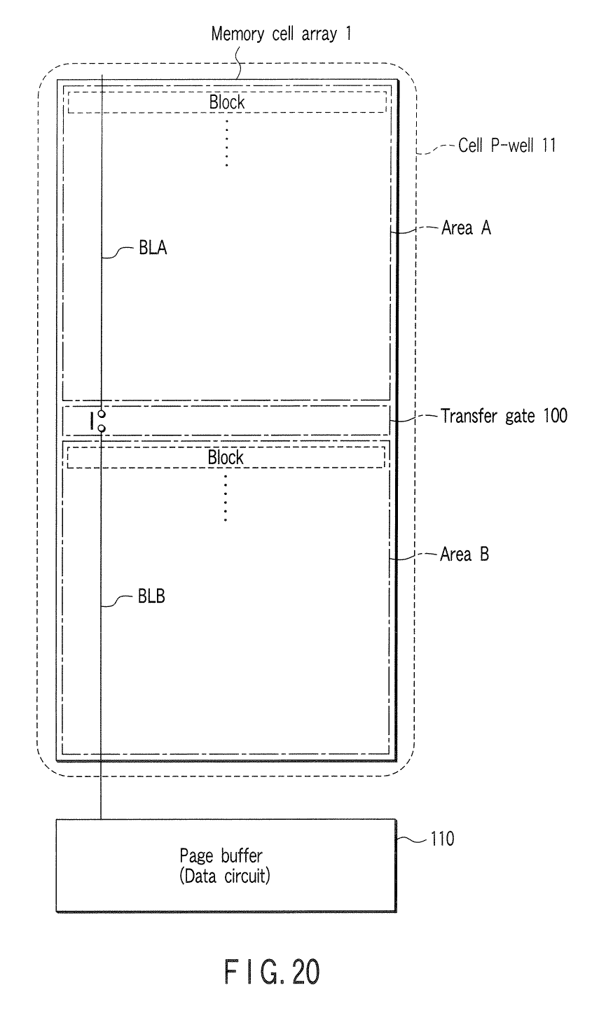

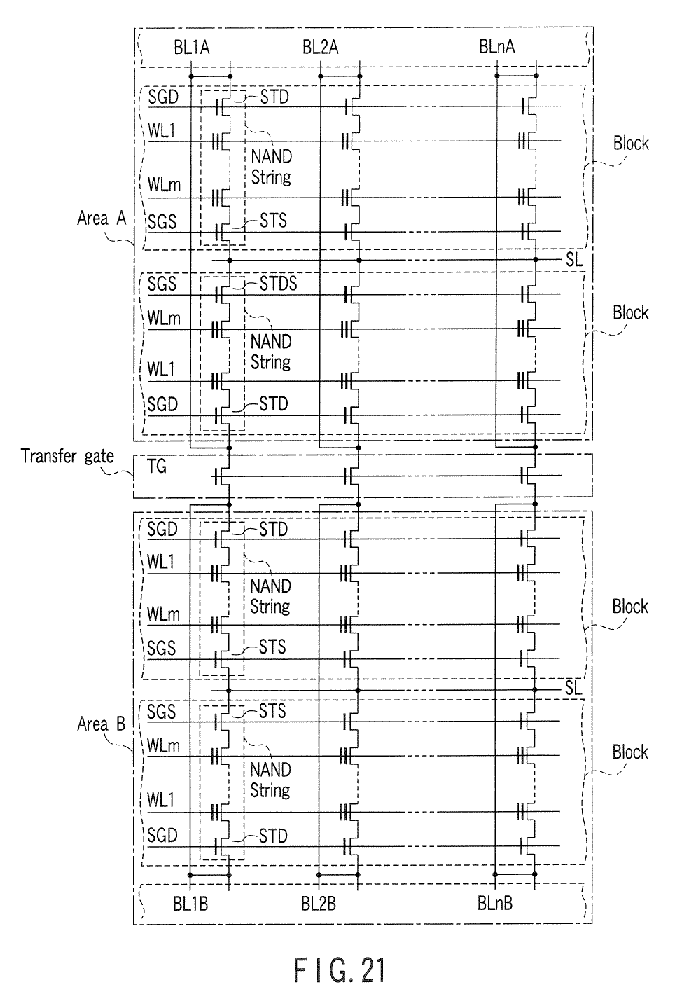

FIG. 20 is a plan view showing one example of the semiconductor integrated circuit device according to the first embodiment of this invention and FIG. 21 is a circuit diagram showing one example of the equivalent circuit of a memory cell array shown in FIG. 20.

As shown in FIGS. 20 and 21, in the first embodiment, the memory cell array 1 is divided into two areas, that is, an area A and area B. Each bit line BL is divided into a sub-bit line BLA (BL1A, BL2A to BLnA) and a sub-bit line BLB (BL1B, BL2B to BLnB) by a transfer gate 100. Like the memory cell array 1, the transfer gate 100 is arranged in a cell P-well 11. Since the transfer gate 100 is arranged in the same cell P-well 11 as that in which the memory cell array 1 is arranged, an advantage that a well-well isolation region is not necessary because of the presence of the transfer gate 100 can be attained. Therefore, even when the transfer gate 100 is provided, an advantage that an increase in the area can be suppressed can be attained. For example, if the transfer gate 100 is configured by high-voltage transistors formed on a P-type substrate, the chip size is increased by 3%. On the other hand, if the transfer gate 100 is arranged in the same cell P-well 11 as that in which the memory cell array 1 is arranged, the chip size is increased only 0.3% or less.

When the area A is accessed, the transfer gate 100 is turned on. In this case, it is assumed that the bit line capacitance is “CBL”.

When the area B is accessed, the transfer gate 100 is turned off. In this case, the bit line capacitance is reduced to “CBL×(½)”.

The bit line capacitance CBL is set to “CBL×(¾)” as an average of the capacitances for the areas A and B and thus the bit line capacitance CBL can be apparently set to a small value. Since the bit line capacitance CBL can be apparently reduced, the read, write and erase operation speeds can be enhanced.

Next, some circuit examples of the transfer gate are explained.

### FIRST EXAMPLE

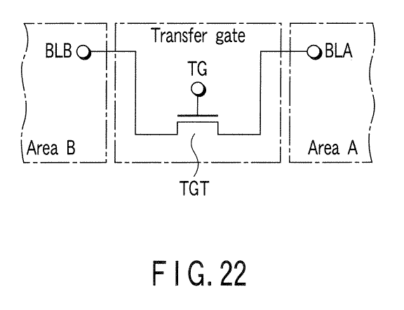

FIG. 22 is a circuit diagram showing a first example of the transfer gate.

As shown in FIG. 22, the first example of the transfer gate is a selection transistor. For example, one example of the selection transistor is a transistor having the same structure as the selection transistor STS or STD in the NAND string shown in FIG. 21. By forming the transfer gate as a transistor having the same structure as the selection transistor STS or STD, for example, an advantage that the transfer gate can be formed in the same manufacturing process as that for forming the selection transistor STS or STD can be attained. The transfer gate may be formed by use of a manufacturing method which is partially common to the manufacturing process for forming the selection transistor STS or STD even when the transfer gate is not formed to have the same structure as the selection transistor STS or STD. In the above cases, an advantage that at least part of the manufacturing process can be commonly used can be attained.

Information that the transfer gate is formed in the same manufacturing process as that for forming the selection transistor STS or STD or in the manufacturing process which is partly common to that for forming the selection transistor STS or STD can be attained based on the thickness of the gate insulating film of the transfer gate, for example. If the thickness of the gate insulating film of the selection transistor contained in the transfer gate is equal to the thickness of the gate insulating film of the selection transistor STS or STD contained in the memory cell array 1, for example, it is safe to say that at least part of the manufacturing process has been commonly used.

Further, in the above example, the selection transistor contained in the transfer gate is formed to have the same structure as the selection transistor STS or STD, but there is provided a nonvolatile semiconductor memory having no selection transistors. For example, it is a NOR flash memory. In this case, the selection transistor contained in the transfer gate may be formed to have the same structure as the memory cell contained in the memory cell array 1. Of course, in this case, the transfer gate is not necessarily formed to have the same structure as the memory cell and may be formed by a manufacturing process which is partly common to the manufacturing process for forming the memory cell.

Information that the transfer gate is formed in the same manufacturing process as that for forming the memory cell or in the manufacturing process which is partly common to that for forming the memory cell can be attained based on the thickness of the gate insulating film of the transfer gate, for example. If the thickness of the gate insulating film of the selection transistor contained in the transfer gate is equal to the thickness of the gate insulating film of the gate of the memory cell contained in the memory cell array 1, for example, it is safe to say that at least part of the manufacturing process has been commonly used.

When the transfer gate of the first example is turned on, potential Vread or Vcc may be applied to the gate TG of a selection transistor TGT. Further, when it is turned off, 0V is applied to the gate TG.

### SECOND EXAMPLE

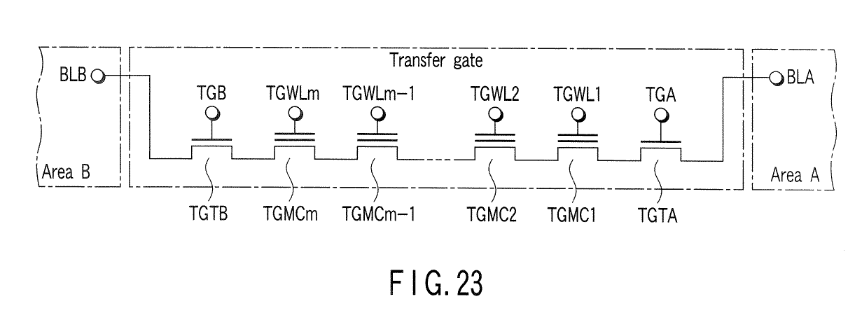

FIG. 23 is a circuit diagram showing a second example of the transfer gate.

As shown in FIG. 23, the NAND string itself can be used as the transfer gate. In this case, the transfer gate can be formed in the same manufacturing process as that for forming the NAND strings contained in the memory cell array 1. Further, the size of the selection transistor and the size of the memory cell can be made exactly the same as the NAND string contained in the memory cell array 1. An advantage attained in this case is that the repetitive pattern can be maintained even when the transfer gate is provided in the memory cell array 1. The fact that the repetitive pattern is maintained means that the process using the lithography technique can be easily performed even if a fine pattern size is used. This is advantageous in miniaturization.

When the transfer gate of the second example is turned on, potential Vcc may be applied to the gate TGA of a selection transistor TGTA and the gate TGB of a selection transistor TGTB, for example. Further, when memory cells TGMC1 to TGMCm are set in the erase state, for example, ground potential may be applied to the gates TGWL1 to TGWLm of the memory cells TGMC1 to TGMm.

When data is erased in the memory cell arranged in the memory cell array 1, a potential of approximately 20V is applied to the cell P-well 11. In order to lower the voltage applied to the gate insulating film of the transfer gate, first, the gate TGA of the selection transistor TGTA and the gate TGB of the selection transistor TGTB are set into an electrically floating state when data is erased. Then, the potential of the cell P-well 11 is raised to a potential of approximately 20V. The potentials of the gates TGA, TGB are raised to approximately 20V due to the capacitive coupling with the cell P-well 11.

Thus, there occurs no possibility that high voltage is applied to the gate insulating films of the selection transistors TGTA, TGTB. Therefore, degradation of the selection transistors TGTA, TGTB can be suppressed and the high reliability of the transfer gate can be maintained for a long period of time.

### THIRD EXAMPLE

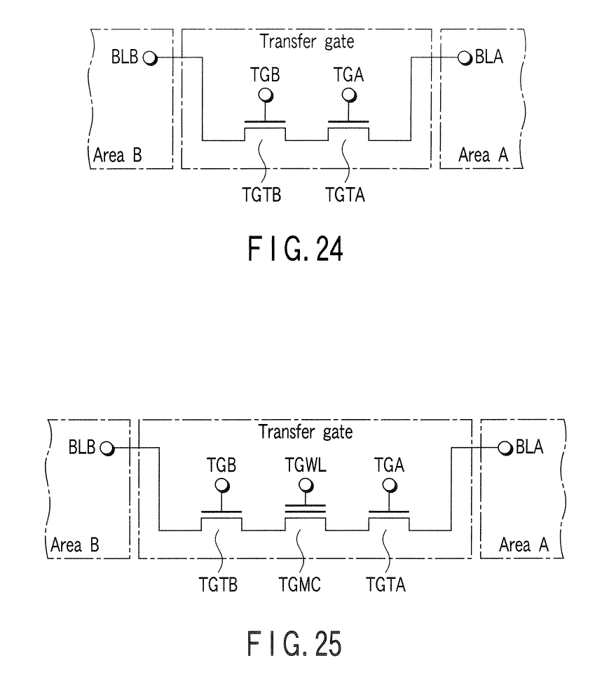

FIG. 24 is a circuit diagram showing a third example of the transfer gate.

For example, the transfer gate may be formed of a 2-selection transistor type obtained by omitting the memory cells from the transfer gate of the second example. For example, when the minimum rule is determined by the leading-edge fine pattern technology, the transfer gate of the second example can be more easily manufactured, but the minimum rule is set more loosely than that determined by the leading-edge fine pattern technology in some cases. In this case, it becomes advantageous for miniaturization by omitting memory cells even if a portion in which the repetitive pattern cannot be maintained is provided in the memory cell array 1.

For example, whether the transfer gate of the second example or the transfer gate of the third example is used may be adequately determined by taking the minimum rule applied into consideration.

### FOURTH EXAMPLE

FIG. 25 is a circuit diagram showing a fourth example of the transfer gate.

For example, the transfer gate may be configured by omitting part of the memory cells instead of omitting all of the memory cells as shown in the third example. In this example, a case wherein one memory cell TGMC is inserted between two selection transistors TGTA and TGTB is shown as one example.

Further, as the nonvolatile semiconductor memory cell, a memory cell called a 3-transistor cell is provided. In this case, the memory cell is the transfer gate itself shown in FIG. 25.

In a memory cell array having 3-transistor cells integrated therein, transfer gates shown in FIG. 25 may be used. In this case, as explained in the second example, an advantage that the repetitive pattern is maintained in the memory cell array can be attained.

### Second Embodiment

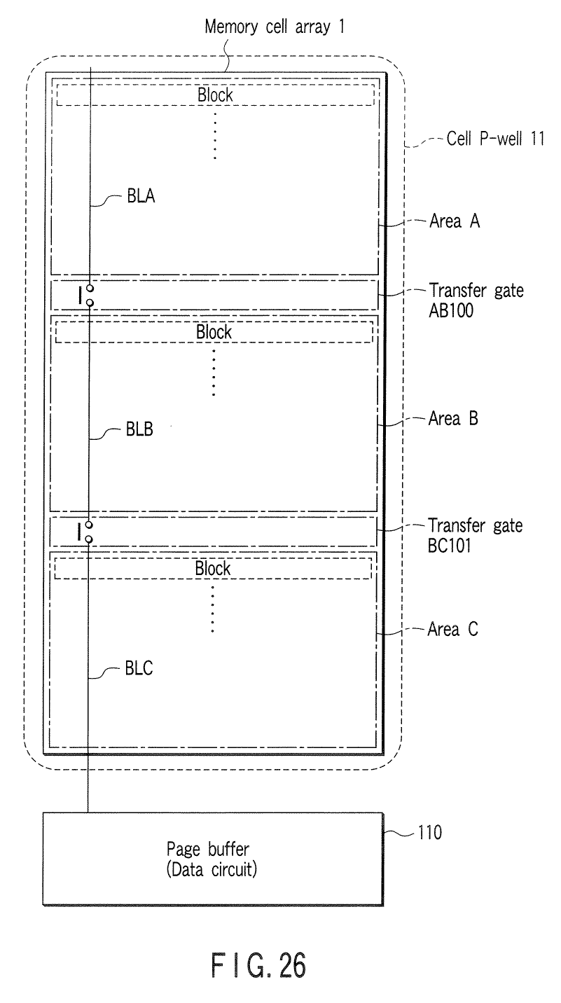

FIG. 26 is a plan view showing one example of a semiconductor integrated circuit device according to a second embodiment of this invention.

As shown in FIG. 26, a memory cell array 1 may be divided into three portions. When an area A is accessed, both of transfer gates AB100 and BC101 are turned on. In this case, it is assumed that the bit line capacitance is set to “CBL”.

When an area B is accessed, the transfer gate AB100 is turned off and the transfer gate BC101 is turned on. In this case, the bit line capacitance is reduced to “CBL×(⅔)”.

When an area C is accessed, both of the transfer gates AB100 and BC101 are turned off. In this case, the bit line capacitance is reduced to “CBL×(⅓)”.

The bit line capacitance CBL is set to “CBL×(⅔)” as an average of the capacitances for the areas A, B and C. Therefore, like the first embodiment, the read, write and erase operation speeds can be enhanced.

### Third Embodiment

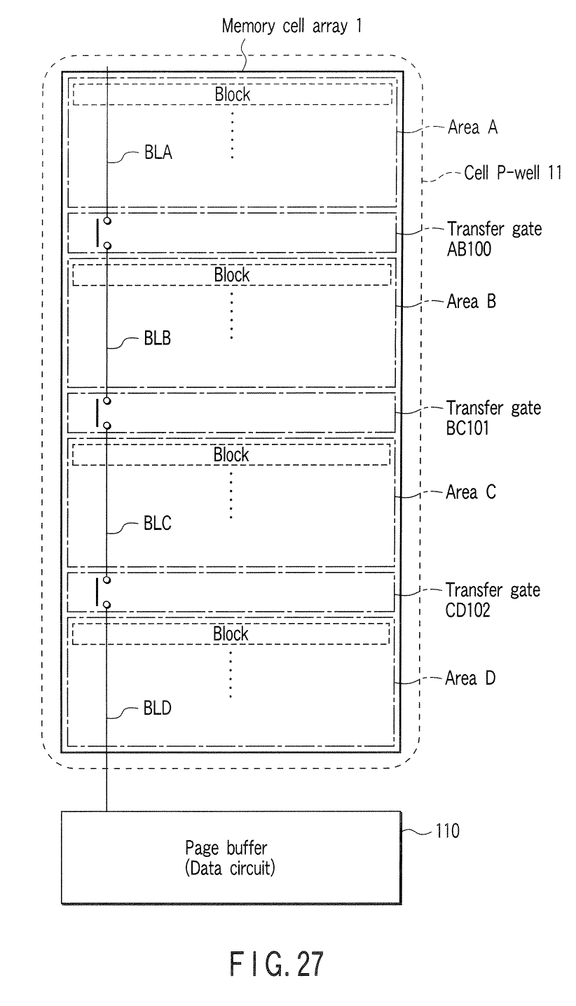

FIG. 27 is a plan view showing one example of a semiconductor integrated circuit device according to a third embodiment of this invention.

As shown in FIG. 27, a memory cell array 1 may be divided into four portions. When an area A is accessed, transfer gates AB100, BC101 and CD102 are all turned on. In this case, it is assumed that the bit line capacitance is set to “CBL”.

When an area B is accessed, the transfer gate AB100 is turned off and the transfer gates BC101 and CD102 are turned on. In this case, the bit line capacitance is reduced to “CBL×(¾)”.

When an area C is accessed, the transfer gates AB100 and BC101 are turned off and the transfer gate CD102 is turned on. In this case, the bit line capacitance is reduced to “CBL×( 2/4)”.

When an area D is accessed, the transfer gates AB100, BC101 and CD102 are all turned off. In this case, the bit line capacitance is reduced to “CBL×(¼)”.

The bit line capacitance CBL is set to “CBL×(⅝)” as an average of the capacitances for the areas A, B, C and D. Therefore, like the first embodiment, the read, write and erase operation speeds can be enhanced.

The above embodiments contain the following items.

(1) A semiconductor integrated circuit device includes a memory cell section containing memory cells, bit lines connected to one end of the memory cell section, and a data circuit connected to the bit lines to temporarily store one of write data and read data with respect to the memory cell, wherein each of the bit lines includes N sub-bit lines and (N-1) transfer gate portions and each of the transfer gate portions includes a selection transistor.

(2) In the device described in item (1), the thickness of the gate insulating film of the selection transistor is equal to that of the gate insulating film of the memory cell contained in the memory cell section.

(3) In the device described in one of items (1) and (2), the memory cell contained in the memory cell section is a NAND memory cell having a plurality of nonvolatile semiconductor memory cells and a selection transistor serially connected.

(4) In the device described in item (1), the transfer gate contains a memory cell and the memory cell contained in the transfer gate is the same memory cell as the memory cell contained in the memory cell section.

(5) In the device described in item (4), the memory cell contained in the transfer gate is the same NAND memory cell as the NAND memory cell contained in the memory cell section.

(6) In the device described in any one of items (1) to (5), the transfer gate is arranged in the same well as that in which the memory cell section is arranged.

(7) In the device described in item (6), the potential of the well is raised to erase voltage after the gate electrode of the memory cell contained in the transfer gate is set into an electrically floating state at the time of erase of data from the memory cell arranged in the well in a case where the memory cell is contained in the transfer gate.

(8) A semiconductor integrated circuit device includes a memory cell section containing NAND memory cells each having a plurality of nonvolatile semiconductor memory cells and a selection transistor serially connected, bit lines connected to one end of the memory cell section, and a data circuit connected to the bit lines to temporarily store one of write data and read data with respect to the NAND memory cell, wherein each of the bit lines includes N sub-bit lines and (N-1) transfer gate portions and each of the transfer gate portions includes at least one selection transistor.

(9) In the device described in item (8), the transfer gate contains a first selection transistor, at least one memory cell and a second selection transistor.

(10) In the device described in item (9), the number of memory cells contained in the transfer gate is the same as the number of memory cells contained in the NAND memory cell.

(11) In the device described in one of items (9) and (10), the transfer gate is arranged in the same well as that in which the memory cell section is arranged.

(12) In the device described in item (11), the potential of the well is raised to erase voltage after the gate electrode of the memory cell contained in the transfer gate is set into an electrically floating state at the time of erase of data from the memory cell arranged in the well.

According to the semiconductor integrated circuit device according to the embodiments of this invention, a semiconductor integrated circuit device having an electrically rewritable nonvolatile semiconductor memory device in which the read, write and erase operation speeds can be enhanced can be provided.

This invention has been explained by use of several embodiments, but this invention is not limited to the above embodiments and is variously modified without departing from the technical scope of this invention at the time of embodying the same.

Further, the above embodiments can be performed independently, but they can be adequately combined and performed.

The above embodiments contain inventions of various stages and the inventions of various stages can be extracted by adequately combining a plurality of constituents disclosed in the embodiments.

In addition, the embodiments are explained based on the example in which this invention is applied to a NAND flash memory. However, this invention is not limited to a NAND flash memory and can also be applied to an AND or NOR flash memory other than a NAND flash memory. Further, a semiconductor integrated circuit device containing the above flash memory, for example, a processor, system LSI or the like is contained in the scope of this invention.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor integrated circuit device comprising:
a memory cell section containing memory cells,
bit lines connected to one end of the memory cell section, and
a data circuit connected to the bit lines to temporarily store one of write data and read data with respect to the memory cell,
wherein each of the bit lines includes N sub-bit lines and (N-1) transfer gate portions and each of the transfer gate portions includes a selection transistor.

2. The device according to claim 1, wherein thickness of a gate insulating film of the selection transistor is substantially equal to that of a gate insulating film of the memory cell contained in the memory cell section.

3. The device according to claim 1, wherein the memory cell contained in the memory cell section is a NAND memory cell having a plurality of nonvolatile semiconductor memory cells and a selection transistor serially connected.

4. The device according to claim 1, wherein the transfer gate contains a memory cell and the memory cell contained in the transfer gate is the same memory cell as the memory cell contained in the memory cell section.

5. The device according to claim 1, wherein the memory cell contained in the transfer gate is the same NAND memory cell as the NAND memory cell contained in the memory cell section.

6. The device according to claim 1, wherein the transfer gate is arranged in the same well as that in which the memory cell section is arranged.

7. The device according to claim 1, wherein potential of the well is raised to erase voltage after a gate electrode of the memory cell contained in the transfer gate is set into an electrically floating state at the time of erase of data from the memory cell arranged in the well in a case where the memory cell is contained in the transfer gate.

8. A semiconductor integrated circuit device comprising:
a memory cell section containing NAND memory cells each having a plurality of nonvolatile semiconductor memory cells and a selection transistor serially connected,
bit lines connected to one end of the memory cell section, and
a data circuit connected to the bit lines to temporarily store one of write data and read data with respect to the NAND memory cell,
wherein each of the bit lines includes N sub-bit lines and (N-1) transfer gate portions and each of the transfer gate portions includes at least one selection transistor.

9. The device according to claim 8, wherein the transfer gate has a first selection transistor, at least one memory cell and second selection transistor.

10. The device according to claim 9, wherein the number of memory cells contained in the transfer gate is the same as the number of memory cells contained in the NAND memory cell.

11. The device according to claim 9, wherein the transfer gate is arranged in the same well as that in which the memory cell section is arranged.

12. The device according to claim 10, wherein the transfer gate is arranged in the same well as that in which the memory cell section is arranged.

13. The device according to claim 11, wherein potential of the well is raised to erase voltage after a gate electrode of the memory cell contained in the transfer gate is set into an electrically floating state at the time of erase of data from the memory cell arranged in the well.

14. The device according to claim 12, wherein potential of the well is raised to erase voltage after a gate electrode of the memory cell contained in the transfer gate is set into an electrically floating state at the time of erase of data from the memory cell arranged in the well.
